(19) United States
(12) Patent Application Publication
(10) Pub. No.: US 2026/0293458 A1
(43) Pub. Date: Sep. 24, 2026

(54) DISPLAY SUBSTRATE AND DISPLAY APPARATUS

(71) Applicants: Nanjing BOE Display Technology CO., LTD., Nanjing,Jiangsu (CN); BOE Technology Group Co., Ltd., Beijing (CN); Beijing BOE Technology Development Co., Ltd., Beijing (CN)

(72) Inventors: Baoze FU, Beijing (CN); Zhilei SUN, Beijing (CN)

(21) Appl. No.: 18/995,979

(22) PCT Filed: May 22, 2024
(86) PCT No.: PCT/CN2024/094675

§ 371 Date: Oct. 16, 2025

(30) Foreign Application Priority Data
Jun. 25, 2023 (CN) 202310755791.8

(51) Int. Cl. H10K 59/131; H10K 59/126

(52) U.S. Cl. CPC H10K 59/131; H10K 59/126

(57) ABSTRACT

A display substrate and a display apparatus. The display substrate has a display area and a non-display area. The display substrate comprises: a base substrate and, arranged on the base substrate, multiple data signal lines at least partially the display area, and at least two selection signal lines, multiple data output lines and a demutiplexer that are in the non-display area. The demutiplexer comprises: multiple selection transistors, the selection transistors being separately and electrically connected to the selection signal lines, the data signal lines and the data output lines. Each selection transistor comprises: a light shading pattern, an active pattern and a gate electrode. For the same selection transistor, one of the light shading pattern and the gate electrode is on the side of the active pattern close to the base substrate, the other one thereof is on the side of the active pattern away from the base substrate.

### CROSS-REFERENCE TO RELATED APPLICATIONS

The present application is a U.S. National Phase Entry of International Application PCT/CN2024/094675 having an international filing date of May 22, 2024, which claims priority of Chinese Patent Application No. 202310755791.8, filed to the CNIPA on Jun. 25, 2023 and entitled “Display Substrate and Display Apparatus”, the content of the above-identified applications should be regarded as being incorporated herein by reference.

### TECHNICAL FIELD

The present disclosure relates to, but is not limited to, the field of display technologies, and more particularly, to a display substrate and a display apparatus.

### BACKGROUND

Mainstream products of displays include liquid crystal displays and organic light emitting diode displays. A display of the above types includes a data drive chip, data lines, data transmission lines, and pixels, wherein the data drive chip outputs data signals to the pixels in the display through the data lines. Due to a large quantity of data lines in the display, the data drive chip correspondingly needs more pins, so that there are correspondingly more data transmission lines for transmitting data signals to each data signal line, which is not conducive to achieving a narrow bezel of the display. In order to realize a full screen, a demultiplexer is disposed between the data drive chip and the data lines, and the data drive chip can be connected to at least two sub-pixels through the demultiplexer, which can greatly reduce a quantity of the data transmission lines, reduce a size of the data drive chip, and reduce a size of the bezel of the display

### SUMMARY

The following is a summary of subject matter described in detail in the present application. This summary is not intended to limit the protection scope of claims.

In a first aspect, the present disclosure further provides a display substrate provided with a display area and a non-display area, comprising a base substrate, a plurality of data signal lines disposed on the base substrate and at least partially located in the display area, at least two selection signal lines, a plurality of data output lines, and a demultiplexer located in the non-display area, wherein the demultiplexer comprises a plurality of selection transistors, and a selection transistor is respectively electrically connected with a selection signal line, a data signal line, and a data output line;
the selection transistor comprises a light shielding pattern, an active pattern, and a gate electrode, wherein for a same selection transistor, one of a light shielding pattern and a gate electrode is located on a side of an active pattern close to the base substrate, the other of the light shielding pattern and the gate electrode is located on a side of the active pattern away from the base substrate, and an orthographic projection of the light shielding pattern on the base substrate is at least partially overlapped with an orthographic projection of the gate electrode on the base substrate; and
the light shielding pattern and the gate electrode of the selection transistor are respectively electrically connected with a selection signal line to which the selection transistor is connected.

In an exemplary implementation, for the same selection transistor, the orthographic projection of the light shielding pattern on the base substrate covers an orthographic projection of the active pattern on the base substrate, and the orthographic projection of the gate electrode on the base substrate is at least partially overlapped with the orthographic projection of the active pattern on the base substrate.

In an exemplary implementation, the selection signal lines comprise a first selection signal line to an M-th selection signal line, and the data output lines comprise a first data output line to an N-th data output line;
the demultiplexer comprises N distributors, wherein an n-th distributor is respectively electrically connected with the first selection signal line to the M-th selection signal line, the n-th data output line, and the M data signal lines, and at least one of the distributors comprises a first selection transistor to an M-th selection transistor;
in the n-th distributor, a light shielding pattern of an m-th selection transistor and a gate electrode of the m-th selection transistor are respectively electrically connected with an m-th selection signal line, wherein 1≤m≤M, and 1≤n≤N;
the data signal lines and the data output lines extend at least partially in a first direction, and the selection signal lines extend at least partially in a second direction, wherein the first direction intersects with the second direction.

In an exemplary implementation, a light shielding pattern has a single-layer structure or a double-layer structure;
when light shielding patterns have double-layer structures, the light shielding pattern comprises a first light shielding pattern and a second light shielding pattern, wherein the first light shielding pattern is located on a side of the second light shielding pattern close to the base substrate, and an orthographic projection of the first light shielding pattern on the base substrate is at least partially overlapped with an orthographic projection of the second light shielding pattern on the base substrate; and
the first light shielding pattern of the light shielding pattern of the selection transistor is insulated from the selection signal line to which the selection transistor is connected, and the second light shielding pattern of the light shielding pattern of the selection transistor is electrically connected with the selection signal line to which the selection transistor is connected.

In an exemplary implementation, when the light shielding pattern has the double-layer structure, a length of the second light shielding pattern in the second direction is larger than a length of the gate electrode of the selection transistor in the second direction.

In an exemplary implementation, when M=2, the n-th distributor comprises: at least one first selection transistor and at least one second selection transistor;
a first electrode of the at least one first selection transistor and a first electrode of the at least one second selection transistor are respectively electrically connected with the n-th data output line, a second electrode of the at least one first selection transistor is electrically connected with a first data signal line to which the n-th distributor is connected, and a second electrode of the at least one second selection transistor is electrically connected with a second data signal line to which the n-th distributor is connected.

In an exemplary implementation, when light shielding patterns have single-layer structures, a light shielding pattern of a first selection transistor and a light shielding pattern of a second selection transistor located in a same distributor are disposed at an interval and arranged in the second direction, and an active pattern of the first selection transistor and an active pattern of the second selection transistor located in the same distributor are arranged at an interval and arranged in the second direction.

In an exemplary implementation, when light shielding patterns have double-layer structures, a first light shielding pattern of a first selection transistor and a first light shielding pattern of a second selection transistor are a same light shielding pattern, a second light shielding pattern of the first selection transistor and a second light shielding pattern of the second selection transistor are disposed at an interval and arranged in the second direction, and an active pattern of the first selection transistor and an active pattern of the second selection transistor are a same active pattern

In an exemplary implementation, when light shielding patterns have double-layer structures, a first light shielding pattern of a first selection transistor and a first light shielding pattern of a second selection transistor are disposed at an interval and arranged in the second direction, a second light shielding pattern of the first selection transistor and a second light shielding pattern of the second selection transistor are disposed at an interval and arranged in the second direction, and an active pattern of the first selection transistor and an active pattern of the second selection transistor are disposed at an interval and arranged in the second direction.

In an exemplary implementation, a structure of the first selection transistor and a structure of the second selection transistor located in the same distributor are at least partially symmetrical with respect to a first virtual straight line, and an extension direction of the first virtual straight line is parallel to the first direction.

In an exemplary implementation, when M=2 and light shielding patterns have single layer structures, the n-th distributor comprises: two first selection transistors and two second selection transistors;
for the n-th distributor, a first electrode of a first one of the first selection transistors is electrically connected with the n-th data output line, a second electrode of the first one of the first selection transistors is electrically connected with a first data signal line to which the n-th distributor is connected, a first electrode of a second one of the first selection transistors is electrically connected with the first selection signal line, a second electrode of the second one of the first selection transistors is electrically connected with a light shielding pattern of the first one of the first selection transistors; a first electrode of a first one of the second selection transistors is electrically connected with the n-th data output line, a second electrode of the first one of the second selection transistors is electrically connected with a second data signal line to which the n-th distributor is connected, a first electrode of a second one of the second selection transistors is electrically connected with a second selection signal line, a second electrode of the second one of the second selection transistors is electrically connected with a light shielding pattern of the first one of the second selection transistors.

In an exemplary implementation, the light shielding pattern of the first one of the first selection transistors and the light shielding pattern of the first one of the second selection transistors are a same light shielding pattern, and an active pattern of the first one of the first selection transistors and an active pattern of the first one of the second selection transistors are a same light shielding pattern; a light shielding pattern of the second one of the first selection transistors and a light shielding pattern of the second one of the second selection transistors are disposed at an interval and arranged in the second direction, and an active pattern of the second one of the first selection transistors and an active pattern of the second one of the second selection transistors are disposed at an interval and arranged in the second direction.

In an exemplary implementation, any one selection signal line includes: a first selection sub-signal line and a second selection sub-signal line, wherein the first selection sub-signal line of any one selection signal line is located on a side of the demultiplexer close to the display area, and the second selection sub-signal line of any selection signal line is located on a side of the demultiplexer away from the display area; and
a gate electrode of the first one of the first selection transistors is electrically connected with a first selection sub-signal line of the first selection signal line, a gate electrode of the first one of the second selection transistors is electrically connected with a first selection sub-signal line of the second selection signal line, a gate electrode and the first electrode of the second one of the first selection transistors are respectively electrically connected with a second selection sub-signal line of the first selection signal line, and a gate electrode and the first electrode of the second one of the second selection transistors are respectively electrically connected with a second selection sub-signal line of the second selection signal line.

In an exemplary implementation, the first one of the first selection transistors and the second one of the first selection transistors are arranged in the first direction, and the first one of the second selection transistors and the second one of the second selection transistors are arranged in the first direction; and
a structure of the first one of the first selection transistors and a structure of the first one of the second selection transistors are at least partially symmetrical with respect to a second virtual straight line, a structure of the second one of the first selection transistors and a structure of the second one of the second selection transistors are at least partially symmetrical with respect to the second virtual straight line, and an extension direction of the second virtual straight line is parallel to the first direction.

In an exemplary implementation, the n-th distributor further comprises: a third selection transistor and a fourth selection transistor; the first one of the first selection transistors is electrically connected with the first data signal line to which the n-th distributor is connected through the third selection transistor, and the first one of the second selection transistors is electrically connected with the second data signal line to which the n-th distributor is connected through the fourth selection transistor;
a gate electrode and a light shielding pattern of the third selection transistor are respectively electrically connected with the first sub-selection signal line of the first selection signal line, a first electrode of the third selection transistor is electrically connected with the first data signal line to which the n-th distributor is connected, and a second electrode of the third selection transistor is electrically connected with the second electrode of the first one of the first selection transistors; and
a gate electrode and a light shielding pattern of the fourth selection transistor are respectively electrically connected with the first sub-selection signal line of the second selection signal line, a first electrode of the fourth selection transistor is electrically connected with the second data signal line to which the n-th distributor is connected, and a second electrode of the fourth selection transistor is electrically connected with the second electrode of the first one of the second selection transistors.

In an exemplary implementation, the light shielding pattern of the third selection transistor and the light shielding pattern of the fourth selection transistor are disposed at an interval and arranged in the second direction, and an active pattern of the third selection transistor and an active pattern of the fourth selection transistor are disposed at an interval and arranged in the second direction.

In an exemplary implementation, the third selection transistor and the fourth selection transistor are located on a side of the first sub-selection signal line close to the display area, and a structure of the third selection transistor and a structure of the fourth selection transistor are at least partially symmetrical with respect to the second virtual straight line.

In an exemplary implementation, when light shielding patterns have single-layer structures, the display substrate comprises a light shielding layer, a semiconductor layer, a first conductive layer, and a second conductive layer sequentially stacked on the base substrate;
the light shielding layer comprises at least: light shielding patterns of the selection transistors;
the semiconductor layer comprises at least: active patterns of the selection transistors;
the first conductive layer comprises at least: gate electrodes of the selection transistors and the selection signal lines; and
the second conductive layer comprises at least: the data signal lines, the data output lines, first electrodes and second electrodes of the selection transistors.

In an exemplary implementation, when light shielding patterns have double-layer structures, the display substrate comprises a first light shielding layer, a second light shielding layer, a semiconductor layer, a first conductive layer, and a second conductive layer sequentially stacked on the base substrate;
the first light shielding layer comprises at least: first light shielding patterns of the selection transistors;
the second light shielding layer comprises at least: second light shielding patterns of the selection transistors;
the semiconductor layer comprises at least: active patterns of the selection transistors;
the first conductive layer comprises at least: gate electrodes of the selection transistors and the selection signal lines; and
the second conductive layer comprises at least: the data signal lines, the data output lines, first electrodes and second electrodes of the selection transistors.

In a second aspect, the present disclosure further provides a display apparatus, including the display substrate described above.

Other aspects of the present disclosure may be comprehended after the drawings and the detailed descriptions are read and understood.

### BRIEF DESCRIPTION OF DRAWINGS

Accompanying drawings are used to provide understanding of technical solutions of the present disclosure, and form a part of the specification. The accompanying drawings and embodiments of the present disclosure are adopted to explain the technical solutions of the present disclosure, and do not form limitations on the technical solutions of the present disclosure.

FIG. 1 is a schematic diagram of a structure of a display substrate.

FIG. 2 is a schematic connection diagram of a selection transistor.

FIG. 3 is a partial cross-sectional diagram of a selection transistor.

FIG. 4 is a schematic diagram of a structure of a demultiplexer.

FIG. 5 is a work timing diagram of selection signal lines and a data output line.

FIG. 6 is a first equivalent circuit diagram of a distributor.

FIG. 7 is a schematic diagram of a structure of a demultiplexer corresponding to FIG. 6.

FIG. 8 is a cross-sectional diagram along an A-A direction of FIG. 7.

FIG. 9 is a second equivalent circuit diagram of a distributor.

FIG. 10 is a schematic diagram of a structure of a demultiplexer corresponding to FIG. 9.

FIG. 11 is a cross-sectional diagram taken along a B-B direction of FIG. 10.

FIG. 12 is a third equivalent circuit diagram of a distributor.

FIG. 13 is a schematic diagram of a structure of a demultiplexer corresponding to FIG. 12.

FIG. 14 is a cross-sectional diagram taken along a C-C direction of FIG. 13.

FIG. 15 is a fourth equivalent circuit diagram of a distributor.

FIG. 16 is a schematic diagram of a structure of a demultiplexer corresponding to FIG. 15.

FIG. 17 is a fifth equivalent circuit diagram of a distributor.

FIG. 18 is a schematic diagram of a structure of a demultiplexer corresponding to FIG. 17.

FIG. 19 is a cross-sectional diagram taken along a D-D direction of FIGS. 16 and 18.

FIG. 20 is a first schematic diagram of a structure of a display area.

FIG. 21 is a second schematic diagram of a structure of a display area.

FIG. 22 is a schematic diagram of a pattern of a light shielding layer in FIG. 7.

FIG. 23 is a schematic diagram of a pattern of a light shielding layer in FIG. 16.

FIG. 24 is a schematic diagram of a pattern of a light shielding layer in FIG. 18.

FIG. 25 is a schematic diagram of a pattern of a semiconductor layer in FIG. 7.

FIG. 26 is a schematic diagram after a pattern of a semiconductor layer is formed in FIG. 7.

FIG. 27 is a schematic diagram of a pattern of a semiconductor layer in FIG. 16.

FIG. 28 is a schematic diagram after a pattern of a semiconductor layer is formed in FIG. 16.

FIG. 29 is a schematic diagram of a pattern of a semiconductor layer in FIG. 18.

FIG. 30 is a schematic diagram after a pattern of a semiconductor layer is formed in FIG. 18.

FIG. 31 is a schematic diagram of a pattern of a first conductive layer in FIG. 7.

FIG. 32 is a schematic diagram after a pattern of a first conductive layer is formed in FIG. 7.

FIG. 33 is a schematic diagram of a pattern of a first conductive layer in FIG. 16.

FIG. 34 is a schematic diagram after a pattern of a first conductive layer is formed in FIG. 16.

FIG. 35 is a schematic diagram of a pattern of a first conductive layer in FIG. 18.

FIG. 36 is a schematic diagram after a pattern of a first conductive layer is formed in FIG. 18.

FIG. 37 is a schematic diagram of a pattern of a third insulation layer in FIG. 7.

FIG. 38 is a schematic diagram of a pattern of a third insulation layer in FIG. 16.

FIG. 39 is a schematic diagram of a pattern of a third insulation layer in FIG. 18.

FIG. 40 is a schematic diagram of a pattern of a second conductive layer in FIG. 7.

FIG. 41 is a schematic diagram after a pattern of a second conductive layer is formed in FIG. 7.

FIG. 42 is a schematic diagram of a pattern of a second conductive layer in FIG. 16.

FIG. 43 is a schematic diagram after a pattern of a second conductive layer is formed in FIG. 16.

FIG. 44 is a schematic diagram of a pattern of a second conductive layer in FIG. 18.

FIG. 45 is a schematic diagram after a pattern of a second conductive layer is formed in FIG. 18.

FIG. 46 is a schematic diagram of a pattern of a first light shielding layer in FIG. 10.

FIG. 47 is a schematic diagram of a pattern of a first light shielding layer in FIG. 13.

FIG. 48 is a schematic diagram of a pattern of a second light shielding layer in FIG. 10.

FIG. 49 is a schematic diagram after a pattern of a second insulation layer is formed in FIG. 10.

FIG. 50 is a schematic diagram of a pattern of a second light shielding layer in FIG. 13.

FIG. 51 is a schematic diagram after a pattern of a second light shielding layer is formed in FIG. 13.

FIG. 52 is a schematic diagram of a pattern of a semiconductor layer in FIG. 10.

FIG. 53 is a schematic diagram after a pattern of a semiconductor layer is formed in FIG. 10.

FIG. 54 is a schematic diagram of a pattern of a semiconductor layer in FIG. 13.

FIG. 55 is a schematic diagram after a pattern of a semiconductor layer is formed in FIG. 13.

FIG. 56 is a schematic diagram of a pattern of a first conductive layer in FIG. 10.

FIG. 57 is a schematic diagram after a pattern of a first conductive layer is formed in FIG. 10.

FIG. 58 is a schematic diagram of a pattern of a first conductive layer in FIG. 13.

FIG. 59 is a schematic diagram after a pattern of a first conductive layer is formed in FIG. 13.

FIG. 60 is a schematic diagram of a pattern of a third insulation layer in FIG. 10.

FIG. 61 is a schematic diagram of a pattern of a third insulation layer in FIG. 13.

FIG. 62 is a schematic diagram of a pattern of a second conductive layer in FIG. 10.

FIG. 63 is a schematic diagram after a pattern of a second conductive layer is formed in FIG. 10.

FIG. 64 is a schematic diagram of a pattern of a second conductive layer in FIG. 13.

FIG. 65 is a schematic diagram after a pattern of a second conductive layer is formed in FIG. 13.

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved apparatuses or elements are required to have specific orientations or are structured and operated in the specific orientations but only for ease of description of the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “disposed in a same layer” adopted refers to a structure formed by patterning two (or more than two) structures through a same patterning process, and their materials may be the same or different. For example, materials of precursors for forming multiple structures disposed in a same layer are the same, and materials finally formed may be the same or different.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” means that a boundary is not defined so strictly and numerical values within process and measurement error ranges are allowed.

A demultiplexer in a display may include a plurality of transistors, and a transistor includes a light shielding pattern and an active pattern. On-state current and mobility of the transistors in the demultiplexer are low, and the light shielding patterns of the transistors in the demultiplexer is in a floating state. When the mobility of the active patterns in the transistors is high, the light shielding patterns in the floating state will cause negative drift influence on characteristics of the transistors, thus affecting a signal transmission capability of the demultiplexer. Therefore, performance of the transistors in the demultiplexer is poor, which affects reliability of the display product.

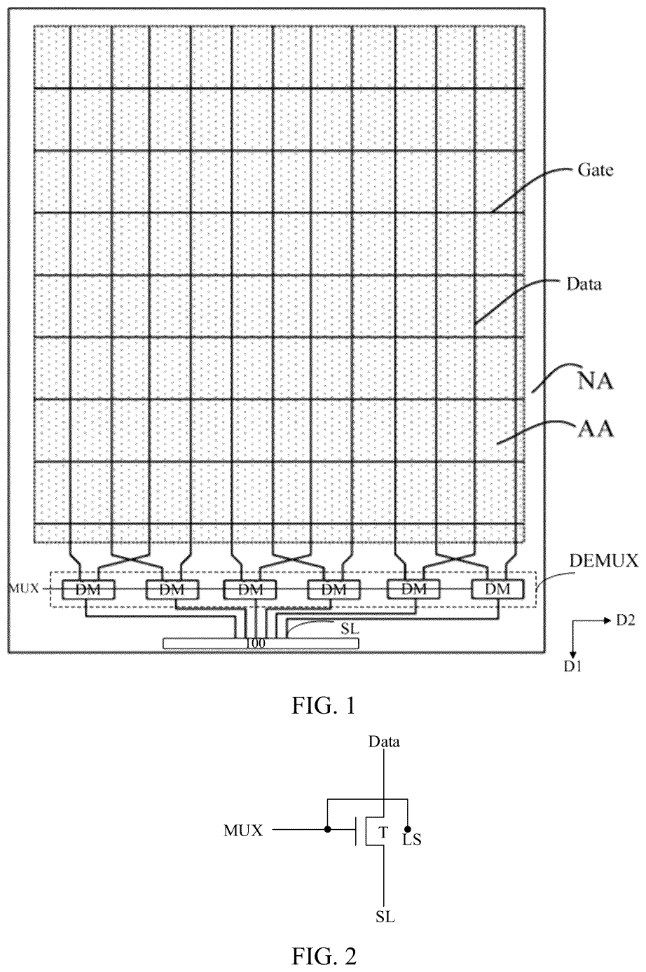

FIG. 1 is a schematic diagram of a structure of a display substrate, FIG. 2 is a schematic connection diagram of a selection transistor, and FIG. 3 is a partial cross-sectional view of a selection transistor. As shown in FIG. 1 to FIG. 3, a display substrate provided in an embodiment of the present disclosure includes a display area AA and a non-display area NA. The display substrate may include a base substrate 10, a plurality of data signal lines Data disposed on the base substrate 10 and at least partially located in the display area and at least two selection signal lines MUX, a plurality of data output lines SL, and a demultiplexer DEMUX located in the non-display area. The demultiplexer DEMUX includes a plurality of selection transistors, and a selection transistor T is electrically connected with a selection signal line MUX, a data signal line Data, and a data output line SL respectively.

In an exemplary implementation, as shown in FIGS. 2 and 3, the selection transistor includes a light shielding pattern LS, an active pattern TA, and a gate electrode TG, and for a same selection transistor, one of a light shielding pattern LS and a gate electrode TG is located on a side of an active pattern LS close to the base substrate 10 and the other of the light shielding pattern LS and the gate electrode TG is located on a side of the active pattern LS away from the base substrate 10, and an orthographic projection of the light shielding pattern LS on the base substrate 10 is at least partially overlapped with an orthographic projection of the gate electrode TG on the base substrate 10. The light shielding pattern LS and the gate electrode of the selection transistor are respectively electrically connected with the selection signal line MUX to which the selection transistor is connected.

In an exemplary implementation, the base substrate 10 may be a rigid base substrate or a flexible base substrate. The rigid base substrate may be, but is not limited to, one or more of glass and conductive foil, the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In the present disclosure, the light shielding pattern LS and the gate electrode TG are respectively located on two sides of the active pattern TA, the orthographic projection of the light shielding pattern LS on the base substrate 10 is at least partially overlapped with the orthographic projection of the gate electrode TG on the base substrate 10, and the light shielding pattern LS and the gate electrode of the selection transistor are respectively electrically connected with the selection signal line MUX to which the selection transistor is connected, which means that the light shielding pattern LS may also serve as one gate electrode of the selection transistor, to form a double gate structure with the gate electrode TG.

In an exemplary implementation, the display substrate may further include a source driver located in the non-display area NA. The source driver is electrically connected with the plurality of data output lines SL. The demultiplexer is located on a side of the source driver close to the display area.

In an exemplary implementation, the display substrate may be an array substrate in a liquid crystal display, or may be an organic light emitting diode display substrate.

A display substrate provided in an embodiment of the present disclosure is provided with a display area and a non-display area, and includes a base substrate and a plurality of data signal lines disposed on the base substrate and at least partially located in the display area and at least two selection signal lines, a plurality of data output lines, and a demultiplexer located in the non-display area. The demultiplexer includes a plurality of selection transistors, and a selection transistor is respectively electrically connected with a selection signal line, a data signal line, and a data output line. The selection transistor includes a light shielding pattern, an active pattern, and a gate electrode, wherein for a same selection transistor, one of a light shielding pattern and a gate electrode is located on a side of an active pattern close to the base substrate, the other of the light shielding pattern and the gate electrode is located on a side of the active pattern away from the base substrate, and an orthographic projection of the light shielding pattern on the base substrate is at least partially overlapped with an orthographic projection of the gate electrode on the base substrate. The light shielding pattern and the gate electrode of the selection transistor are respectively electrically connected with a selection signal line to which the selection transistor is connected. In the present disclosure, the orthographic projection of the light shielding pattern on the base substrate is at least partially overlapped with the orthographic projection of the gate electrode on the base substrate. The light shielding pattern and the gate electrode of the selection transistor are respectively electrically connected with the selection signal line to which the selection transistor is connected, thereby avoiding a floating state of the light shielding pattern of the selection transistor, reducing an influence of negative drift on the characteristics of the transistor, improving a signal transmission capability of the demultiplexer. Moreover, by forming a double gate structure with the light shielding pattern and the gate electrode, the on-state current and the mobility of the selection transistor are improved, thereby improving the reliability of the display product.

In an exemplary implementation, as shown in FIG. 2, for the same selection transistor, the orthographic projection of the light shielding pattern LS on the base substrate 10 covers an orthographic projection of the active pattern TA on the base substrate, and the orthographic projection of the gate electrode TG on the base substrate 10 is at least partially overlapped with the orthographic projection of the active pattern TA on the base substrate 10.

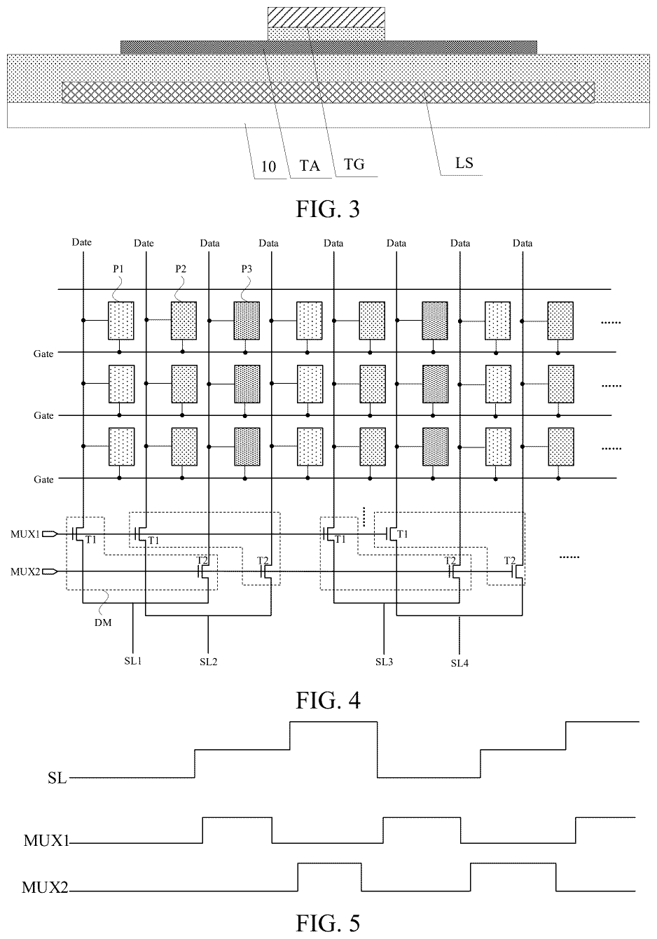

FIG. 4 is a schematic diagram of a structure of a demultiplexer. As shown in FIG. 4, the selection signal lines includes a first selection signal line to an M-th selection signal line, and the data output lines include a first data output line to an N-th data output line. In FIG. 4, illustration is made by taking an example in which M=2, and only four data output lines SL1 to SLA and a first selection signal line MUX1 and a second selection signal line MUX2 are shown in FIG. 4.

In an exemplary implementation, as shown in FIGS. 1 and 4, the demultiplexer DEMUX includes N distributors DM, wherein an n-th distributor DM is respectively electrically connected with a first selection signal line to an M-th selection signal line, an n-th data output line, and M data signal lines, and at least one distributor includes a first selection transistor to an M-th selection transistor. FIG. 4 is illustrated by taking an example in which the at least one distributor includes a first selection transistor T1 to a second selection transistor T2.

In an exemplary implementation, as shown in FIG. 4, all selection transistors in the demultiplexer may be of a same transistor type. For example, any one of the first selection transistor to the M-th selection transistor may be an N-type transistor.

In an exemplary implementation, as shown in FIG. 4, in the n-th distributor, a light shielding pattern of an m-th selection transistor and a gate electrode of the m-th selection transistor are respectively electrically connected with an m-th selection signal line, wherein 1≤m≤M, and 1≤n≤N. For example, a light shielding pattern of the first selection transistor T1 and a gate electrode of the first selection transistor are respectively electrically connected with the first selection signal line MUX1, and a light shielding pattern of the second selection transistor T2 and a gate electrode of the second selection transistor are respectively electrically connected with the second selection signal line MUX2.

In an exemplary implementation, FIG. 5 is a work timing diagram of selection signal lines and a data output line. As shown in FIG. 5, when one of the plurality of selection signal lines is in an active level signal, the other of the plurality of selection signal lines is in an inactive level signal. For example, as shown in FIGS. 4 and 5, when M=2, a signal MUX1 of the first selection signal line and a signal of the second selection signal line MUX2 are not active level signals simultaneously. When the signal of the signal MUX1 of the first selection signal line is an active level signal, the first selection transistor T1 is turned on, and a signal of the data output line SL is written into a data signal line to which the first selection transistor T1 is connected. At this stage, when the signal of the signal MUX2 of the second selection signal line is an inactive level signal, the second selection transistor T2 is turned off. When the signal of the signal MUX 2 of the second selection signal line is an active level signal, the second selection transistor T2 is turned on, and the signal of the data output line SL is written into a data signal line to which the second selection transistor T2 is connected.

In an exemplary implementation, as shown in FIGS. 1 and 4, the data signal lines Data and the data output lines SL extend at least partially in a first direction D1, the selection signal lines MUX extend at least partially in a second direction D2, wherein the first direction intersects with the second direction.

In an exemplary implementation, a light shielding pattern may have a single-layer structure or a double-layer structure.

In an exemplary implementation, when the light shielding pattern has a double-layer structure, the light shielding pattern includes a first light shielding pattern and a second light shielding pattern, wherein the first light shielding pattern is located on a side of the second light shielding pattern close to the base substrate, and an orthographic projection of the first light shielding pattern on the base substrate is at least partially overlapped with an orthographic projection of the second light shielding pattern on the base substrate.

In an exemplary implementation, a first light shielding pattern of light shielding patterns of the selection transistor is insulated from a selection signal line to which the selection transistor is connected, and a second light shielding pattern of the light shielding patterns of the selection transistor is electrically connected with the selection signal line to which the selection transistor is connected.

In an exemplary implementation, when the light shielding pattern has a double-layer structure, a length of the second light shielding pattern of the light shielding patterns of the selection transistor in the second direction is larger than a length of the gate electrode of the selection transistor in the second direction.

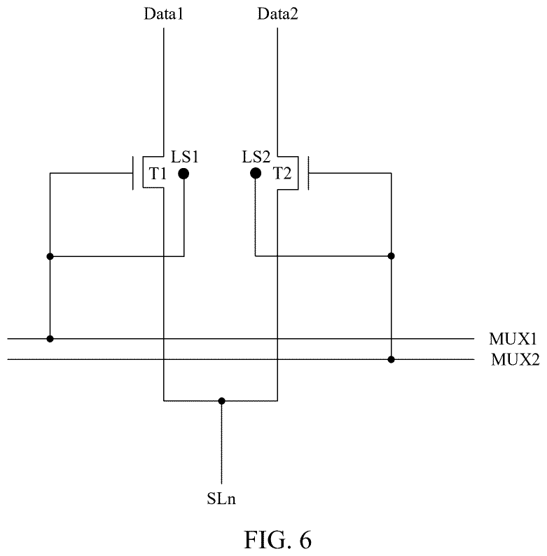

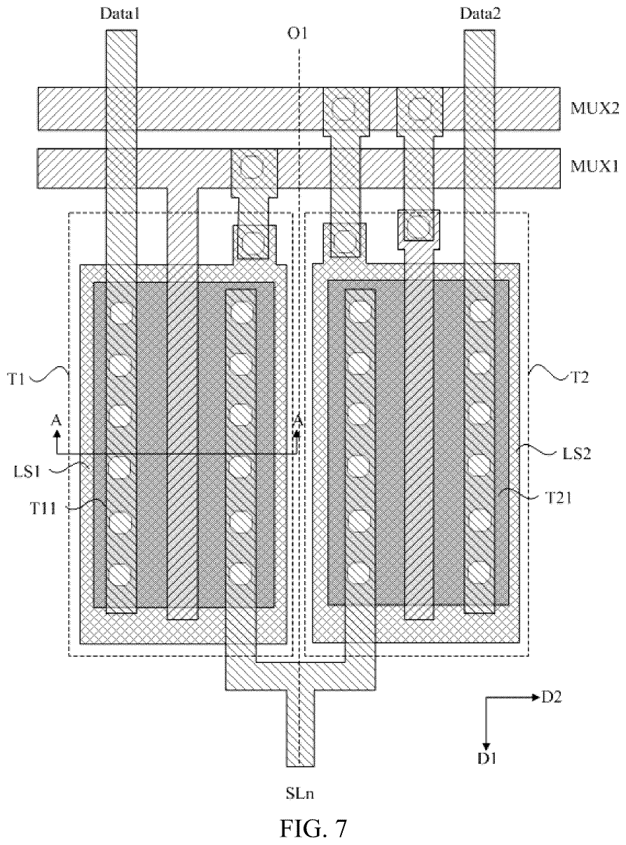

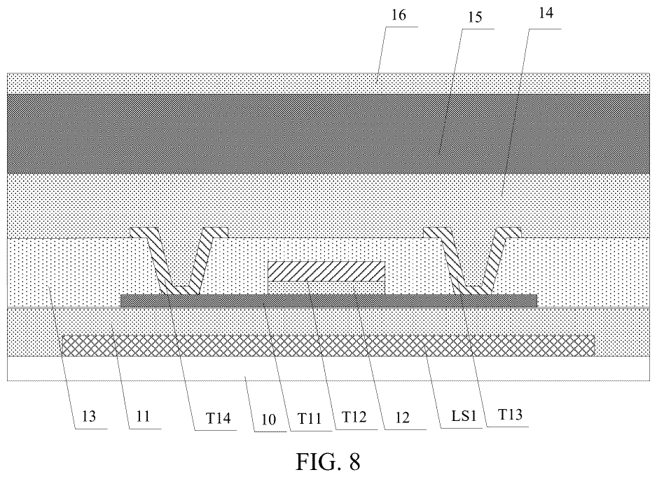

FIG. 6 is a first equivalent circuit diagram of a distributor, FIG. 7 is a schematic diagram of a structure of a demultiplexer corresponding to FIG. 6, and FIG. 8 is a cross-sectional view taken along an A-A direction of FIG. 7. FIGS. 6 to 8 are illustrated by taking an example in which M=2 and light shielding patterns have single-layer structures. As shown in FIGS. 6 to 8, when M=2, the n-th distributor includes a first selection transistor T1 and a second selection transistor T2. Herein, a light shielding pattern LS1 and a gate electrode of the first selection transistor T1 are electrically connected with a first selection signal line MUX1, a light shielding pattern LS2 and a gate electrode of the second selection transistor T2 are electrically connected with a second selection signal line MUX2, a first electrode of the first selection transistor T1 and a first electrode of the second selection transistor T2 are electrically connected with the n-th data output line SLn, a second electrode of the first selection transistor T1 is electrically connected with a first data signal line Data1 to which the n-th distributor is connected, and a second electrode of the second selection transistor T2 is electrically connected with a second data signal line Data2 to which the n-th distributor is connected.

In an exemplary implementation, as shown in FIGS. 6 to 8, a light shielding pattern LS1 of the first selection transistor and a light shielding pattern LS2 of the second selection transistor located in the same distributor are disposed at an interval from each other and are arranged in the second direction D2, and an active pattern T11 of the first selection transistor and an active pattern T12 of the second selection transistor located in the same distributor are disposed at an interval from each other and are arranged in the second direction D2.

In an exemplary implementation, the demultiplexer provided in FIGS. 6 to 8 avoids the light shielding patterns of the selection transistors being in a floating state, which can reduce the influence of negative drift on the characteristics of the transistors, improve the signal transmission capability of the demultiplexer, and also form double gate structures with a light shielding patterns and gate electrodes, improve the on-state current and the mobility of the selection transistors, improve the reliability of the display product, and do not add a mask, and do not cause an increase in cost.

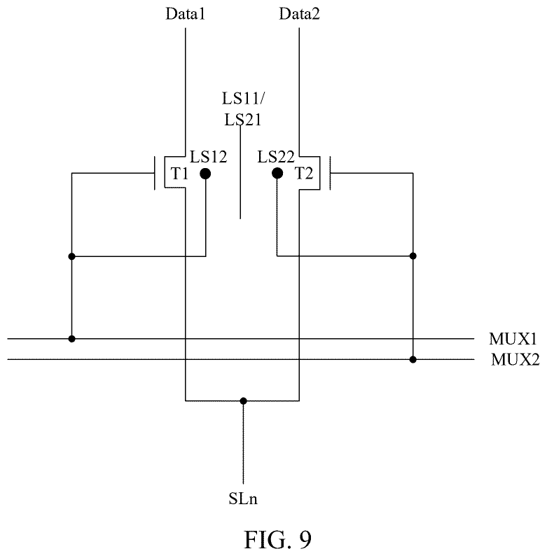

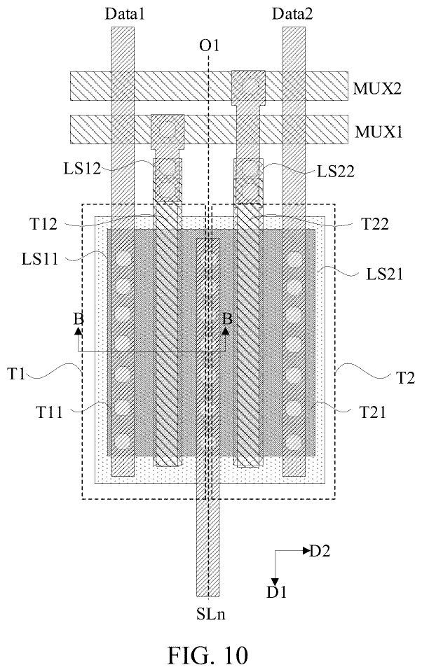

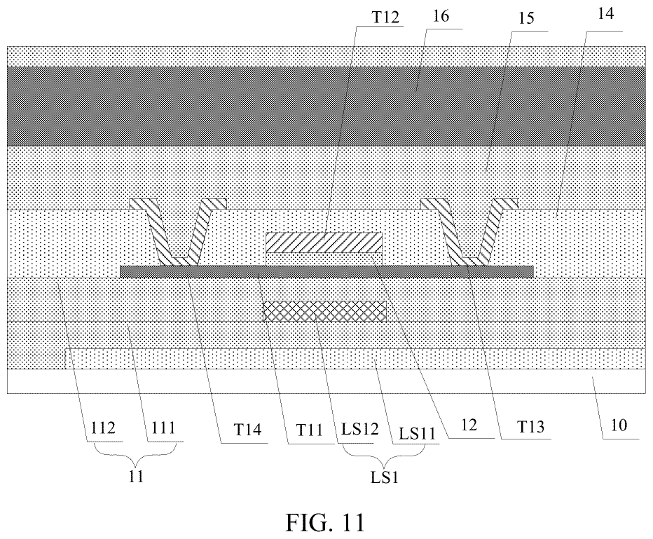

FIG. 9 is a second equivalent circuit diagram of a distributor, FIG. 10 is a schematic diagram of a structure of a demultiplexer corresponding to FIG. 9, and FIG. 11 is a cross-sectional view taken along a B-B direction of FIG. 10. FIGS. 9 to 11 are illustrated by taking an example in which M=2 and light shielding patterns have double-layer structures. As shown in FIGS. 9 to 11, when M=2, an n-th distributor includes a first selection transistor T1 and a second selection transistor T2. Herein, a light shielding pattern LS1 of the first selection transistor T1 includes a first light shielding pattern LS11 and a second light shielding pattern LS12, and a light shielding pattern LS2 of the second selection transistor T2 includes a first light shielding pattern LS21 and a second light shielding pattern LS22. The first light shielding pattern LS11 of the light shielding pattern LS1 of the first selection transistor T1 is insulated from a first selection signal line MUX1, a gate electrode and the second light shielding pattern LS12 of the light shielding pattern LS1 of the first selection transistor T1 are electrically connected with the first selection signal line MUX1, and the first light shielding pattern LS21 of the light shielding pattern LS2 of the second selection transistor T2 is insulated from a second selection signal line MUX2, a gate electrode and the second light shielding pattern LS22 of the light shielding pattern LS2 of the second selection transistor T2 are electrically connected with a second selection signal line MUX2, a first electrode of the first selection transistor T1 and a first electrode of the second selection transistor T2 are respectively electrically connected with an n-th data output line SLn, a second electrode of the first selection transistor T1 is electrically connected with a first data signal line Data1 to which the n-th distributor is connected, and a second electrode of the second selection transistor T2 is electrically connected with a second data signal line Data2 to which the n-th distributor is connected.

In an exemplary implementation, as shown in FIGS. 9 to 11, the first light shielding pattern LS11 of the first selection transistor T1 and the first light shielding pattern LS21 of the second selection transistor T2 are a same light shielding pattern, the second light shielding pattern LS12 of the first selection transistor and the second light shielding pattern LS22 of the second selection transistor are disposed at an interval and arranged in the second direction D2, and an active pattern T11 of the first selection transistor and an active pattern T12 of the second selection transistor are a same active pattern.

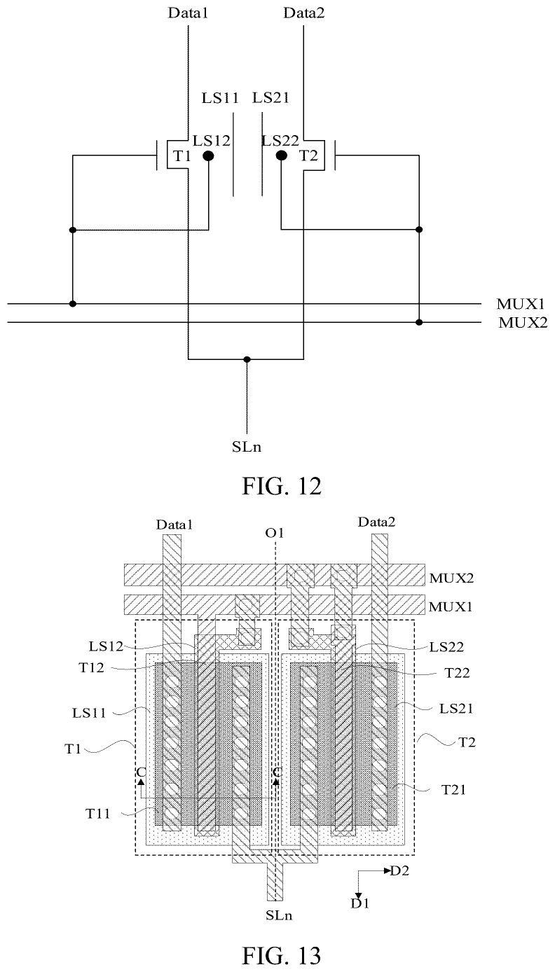

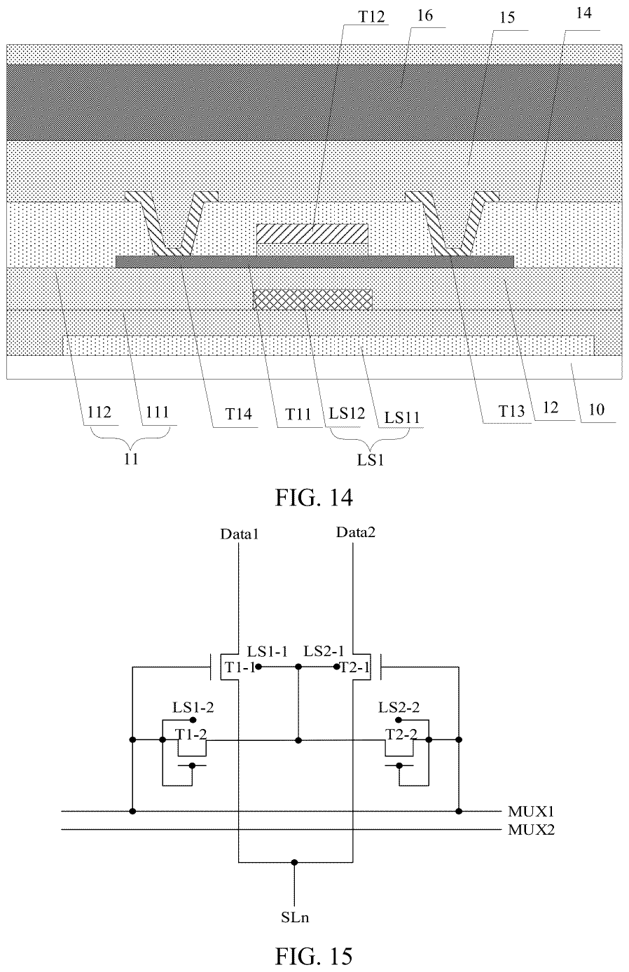

FIG. 12 is a third equivalent circuit diagram of a distributor, FIG. 13 is a schematic diagram of a structure of a demultiplexer corresponding to FIG. 12, and FIG. 14 is a cross-sectional view taken along a C-C direction of FIG. 13. FIGS. 12 to 14 are illustrated by taking an example in which M=2 and light shielding patterns have double-layer structures. As shown in FIGS. 12 to 14, when M=2, an n-th distributor includes a first selection transistor T1 and a second selection transistor T2. Herein, a light shielding pattern LS1 of the first selection transistor T1 includes a first light shielding pattern LS11 and a second light shielding pattern LS12, and a light shielding pattern LS2 of the second selection transistor T2 includes a first light shielding pattern LS21 and a second light shielding pattern LS22. The first light shielding pattern LS11 of the light shielding pattern LS1 of the first selection transistor T1 is insulated from a first selection signal line MUX1, a gate electrode and the second light shielding pattern LS12 of the light shielding pattern LS1 of the first selection transistor T1 are electrically connected with the first selection signal line MUX1, and the first light shielding pattern LS21 of the light shielding pattern LS2 of the second selection transistor T2 is insulated from a second selection signal line MUX2, a gate electrode and the second light shielding pattern LS22 of the light shielding pattern LS2 of the second selection transistor T2 are electrically connected with a second selection signal line MUX2, a first electrode of the first selection transistor T1 and a first electrode of the second selection transistor T2 are respectively electrically connected with an n-th data output line SLn, a second electrode of the first selection transistor T1 is electrically connected with a first data signal line Data1 to which the n-th distributor is connected, and a second electrode of the second selection transistor T2 is electrically connected with a second data signal line Data2 to which the n-th distributor is connected.

In an exemplary implementation, as shown in FIGS. 12 to 14, the first light shielding pattern LS11 of the first selection transistor T1 and the first light shielding pattern LS21 of the second selection transistor T2 are disposed at an interval and arranged in the second direction D2, the second light shielding pattern LS12 of the first selection transistor T1 and the second light shielding pattern LS22 of the second selection transistor T2 are disposed at an interval and arranged in the second direction D2, and an active pattern T11 of the first selection transistor T1 and an active pattern T21 of the second selection transistor T2 are disposed at an interval and arranged in the second direction D2.

In an exemplary implementation, as shown in FIGS. 10 and 13, when the light shielding structures have double-layer structures, a length of the second light shielding pattern LS12 of the first selection transistor T1 in the second direction D2 is larger than a length of the gate electrode T12 of the first selection transistor, and a length of the second light shielding pattern LS22 of the second selection transistor T2 in the second direction D2 is larger than a length of the gate electrode T22 of the second selection transistor. When the length of the second light shielding pattern LS12 of the first selection transistor T1 in the second direction D2 is larger than the length of the gate electrode T12 of the first selection transistor, the second light shielding pattern LS12 of the first selection transistor T1 can shield an interference of the first light shielding pattern LS11 of the first selection transistor T1 to the active pattern T11 of the first selection transistor T1, and when the length of the second light shielding pattern LS22 of the second selection transistor T2 in the second direction D2 is larger than the length of the gate electrode T22 of the second selection transistor T2, the second light shielding pattern LS22 of the second selection transistor T2 can shield an interference of the first light shielding pattern LS21 of the second selection transistor T2 to the active pattern T21 of the second selection transistor T2, thereby improving the reliability of the demultiplexer.

In an exemplary implementation, as shown in FIGS. 7, 10, and 13, any one of the selection signal lines is located on a side of the demultiplexer close to the display area, and a plurality of selection signal lines are arranged in the first direction D1.

In an exemplary implementation, as shown in FIGS. 7, 10, and 13, a structure of the first selection transistor T1 and a structure of the second selection transistor T2 located in a same distributor are at least partially symmetrical with respect to a first virtual straight line O1, and an extension direction of the first virtual straight line O1 is parallel to the first direction D1. Herein, the first virtual straight line O1 is a center line of an orthographic projection of the data output line SLn on the base substrate from a top-down perspective.

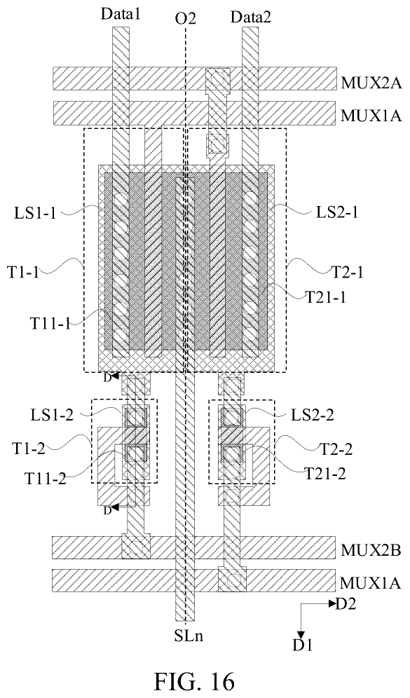

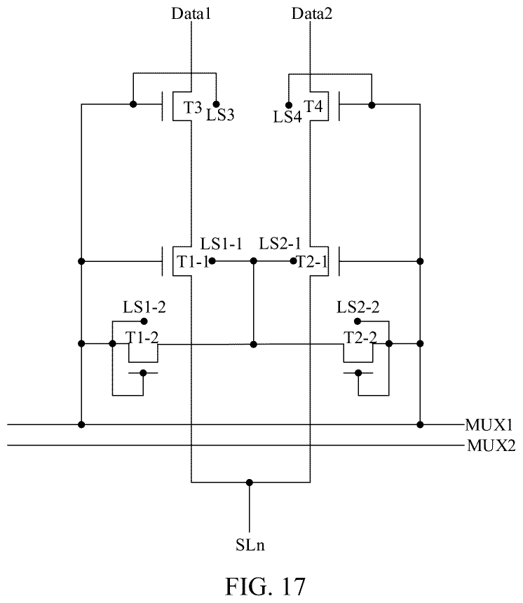

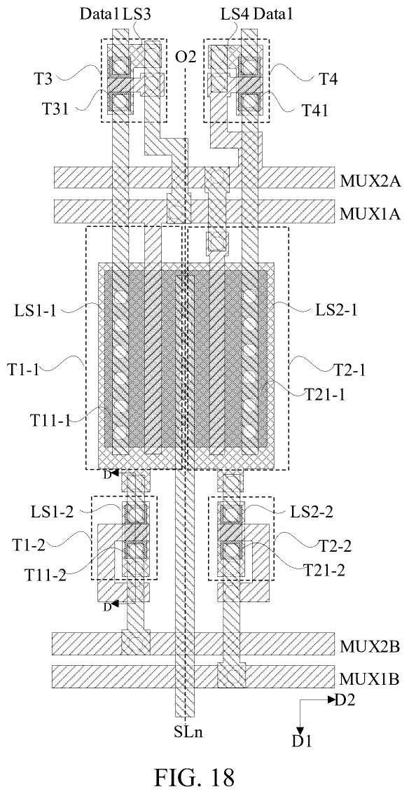

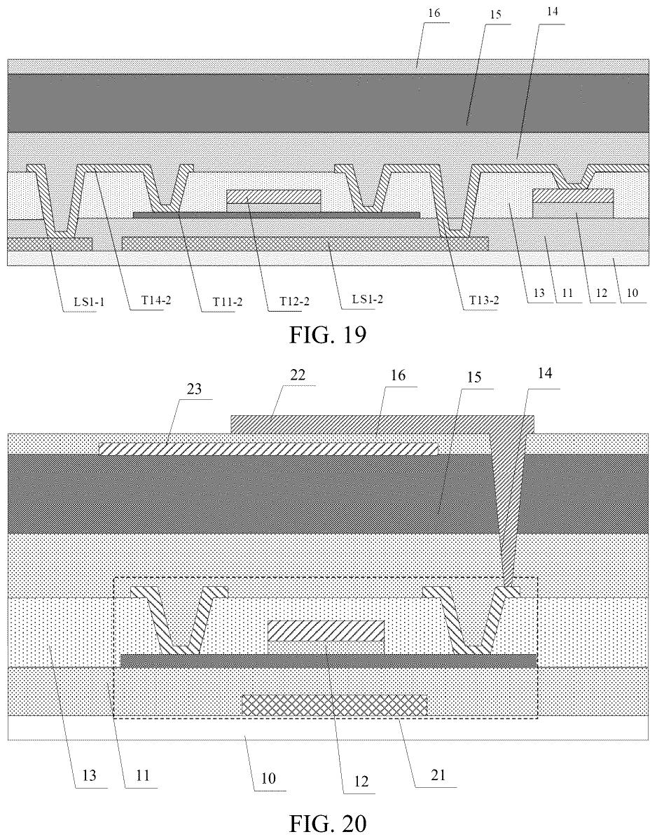

In an exemplary implementation, the demultiplexer provided in FIGS. 9 to 14 avoids the light shielding patterns of the selection transistors being in a floating state, which can reduce the influence of negative drift on the characteristics of the transistors, improve the signal transmission capability of the demultiplexer, and also form double gate structures with light shielding patterns and gate electrodes, improve the on-state current and mobility of the selection transistors, improve the reliability of the display product, and reduce the parasitic capacitance of the demultiplexer.
FIG. 15 is a fourth equivalent circuit diagram of a distributor, FIG. 16 is a schematic diagram of a structure of a demultiplexer corresponding to FIG. 15, FIG. 17 is a fifth equivalent circuit diagram of a distributor, FIG. 18 is a schematic diagram of a structure of a demultiplexer corresponding to FIG. 17, and FIG. 19 is a cross-sectional view taken along a D-D direction of FIGS. 16 and 18. FIGS. 15 to 19 are illustrated by taking an example in which M=2 and light shielding patterns have single-layer structures. As shown in FIGS. 15 to 19, when M=2 and the light shielding patterns have single-layer structures, an n-th distributor includes two first selection transistors T1-1 and T1-2, and two second selection transistors T2-1 and T2-2. Herein, for the n-th distributor, a gate electrode of a first one of the first selection transistors T1-1 is electrically connected with a first selection signal line MUX1, a light shielding structure LS1-1 of the first one of the first selection transistors T1-1 is electrically connected with a second electrode of a second one of the first selection transistors T1-2, a light shielding structure LS1-2 and a gate electrode of the second one of the first selection transistors T1-2 are respectively electrically connected with the first selection signal line MUX1, a first electrode of the first one of the first selection transistors T1-1 is electrically connected with an n-th data output line SLn, a second electrode of the first one of the first selection transistors T1-1 is electrically connected with a first data signal line Data1 to which the n-th distributor is connected, a first electrode of the second one of the first selection transistors T1-2 is electrically connected with the first selection signal line MUX1, the second electrode of the second one of the first selection transistors T1-2 is electrically connected with the light shielding pattern LS1-1 of the first one of the first selection transistors; a gate electrode of a first one of the second selection transistors T2-1 is electrically connected with a second selection signal line MUX2, a light shielding structure LS2-1 of the first one of the second selection transistors T2-1 is electrically connected with a second electrode of a second one of the second selection transistors T2-2, a light shielding structure LS2-2 and a gate electrode of the second one of the second selection transistors T2-2 are respectively electrically connected with the second selection signal line MUX2, a first electrode of the first one of the second selection transistors T2-1 is electrically connected with the n-th data output line SLn, a second electrode of the first one of the second selection transistors T2-1 is electrically connected with a second data signal line Data2 to which the n-th distributor is connected, a first electrode of the second one of the second selection transistors T2-2 is electrically connected with the second selection signal line MUX2, the second electrode of the second one of the second selection transistors T2-2 is electrically connected with the light shielding pattern LS2-1 of the first one of the second selection transistors.

In an exemplary implementation, as shown in FIGS. 16 and 18, any one of the selection signal lines includes a first selection sub-signal line and a second selection sub-signal line, a first selection sub-signal line of any one of the selection signal lines is located on the side of the demultiplexer close to the display area, and a second selection sub-signal line of any one of the selection signal lines is located on a side of the demultiplexer away from the display area. As shown in FIGS. 16 and 18, the first selection signal line includes a first selection sub-signal line MUX1A and a second selection sub-signal line MUX1B, and the second selection signal line includes a first selection sub-signal line MUX2A and a second selection sub-signal line MUX2B.

In an exemplary implementation, as shown in FIGS. 16 and 18, the gate electrode of the first one of the first selection transistors T1-1 is electrically connected with the first selection sub-signal line MUX1A of the first selection signal line, the gate electrode of the first one of the second selection transistors T2-1 is electrically connected with the first selection sub-signal line MUX2A of the second selection signal line, the gate electrode and the first electrode of the second one of the first selection transistors T1-2 are respectively electrically connected with the second selection sub-signal line MUX1B of the first selection signal line, the gate electrode and the first electrode of the second one of the second selection transistors T2-2 are respectively electrically connected with the second selection sub-signal line MUX2B of the second selection signal line.

In an exemplary implementation, the first selection sub-signal line MUX1A of the first selection signal line may be located on a side of the second selection sub-signal line MUX2A of the second selection signal line close to or away from the display area, and the second selection sub-signal line MUX1B of the first selection signal line may be located on a side of the second selection sub-signal line MUX2B of the second selection signal line close to or away from the display area. FIGS. 16 and 19 are illustrated by taking an example in which the first selection sub-signal line MUX1A of the first selection signal line is located on a side of the second selection sub-signal line MUX2A of the second selection signal line away from the display area, and the second selection sub-signal line MUX1B of the first selection signal line is located on a side of the second selection sub-signal line MUX2B of the second selection signal line away from the display area.

In an exemplary implementation, as shown in FIGS. 17 and 18, the n-th distributor may further include: a third selection transistor T3 and a fourth selection transistor T4; the first one of the first selection transistors T1-1 is electrically connected with the first data signal line Data1 to which the n-th distributor is connected through the third selection transistor T3, and the first one of the second selection transistors T2-1 is electrically connected with the second data signal line Data2 to which the n-th distributor is connected through the fourth selection transistor T4. Herein a gate electrode and a light shielding pattern LS2 of the third selection transistor T3 are respectively electrically connected with the first sub-selection signal line MUX1A of the first selection signal line, a first electrode of the third selection transistor T3 is electrically connected with the first data signal line Data1 to which the n-th distributor is connected, and a second electrode of the third selection transistor T3 is electrically connected with the second electrode of the first one of the first selection transistors T1-1; a gate electrode and a light shielding pattern of the fourth selection transistor T4 are respectively electrically connected with the first sub-selection signal line MUX2A of the second selection signal line, a first electrode of the fourth selection transistor T4 is electrically connected with the second data signal line Data2 to which the n-th distributor is connected, and a second electrode of the fourth selection transistor T4 is electrically connected with the second electrode of the first one of the second selection transistors T2-1.

In an exemplary implementation, as shown in FIGS. 16 and 18, the light shielding pattern LS1-1 of the first one of the first selection transistors T1-1 and the light shielding pattern LS2-1 of the first one of the second selection transistors T2-1 are a same light shielding pattern, and an active pattern T11-1 of the first one of the first selection transistors T1-1 and an active pattern T21-1 of the first one of the second selection transistors T2-1 are a same light shielding pattern; the light shielding pattern LS1-2 of the second one of the first selection transistors T1-2 and the light shielding pattern LS2-2 of the second one of the second selection transistors T2-2 are disposed at an interval from each other and arranged in the second direction D2, and an active pattern T11-2 of the second one of the first selection transistors T1-2 and an active pattern T21-2 of the second one of the second selection transistors T2-2 are disposed at interval from each other and arranged in the second direction D2.

In an exemplary implementation, as shown in FIGS. 16 and 18, the first one of the first selection transistors T1-1 and the second one of the first selection transistors T1-2 are arranged in the first direction D1, and the first one of the second selection transistors T2-1 and the second one of the second selection transistors T2-2 are arranged in the first direction D1.

In an exemplary implementation, as shown in FIGS. 16 and 18, a structure of the first one of the first selection transistors T1-1 and a structure of the first one of the second selection transistors T2-1 are at least partially symmetrical with respect to a second virtual straight line O2, and a structure of the second one of the first selection transistors T1-2 and a structure of the second one of the second selection transistors T2-2 are at least partially symmetrical with respect to the second virtual straight line O2. An extension direction of the second virtual straight line O2 is parallel to the first direction D1, wherein the second virtual straight line O2 is a center line of an orthographic projection of the data output line SLn on the base substrate from the top-down perspective.

In an exemplary implementation, as shown in FIG. 18, the light shielding pattern LS3 of the third selection transistor T3 and the light shielding pattern LS4 of the fourth selection transistor T4 are disposed at an interval and arranged in the second direction D2, and an active pattern T31 of the third selection transistor T3 and an active pattern T41 of the fourth selection transistor T4 are disposed at an interval and arranged in the second direction D2.

In an exemplary implementation, as shown in FIG. 18, the third selection transistor T3 and the fourth selection transistor T4 are located on a side of the first sub-selection signal line close to the display area, and a structure of the third selection transistor T3 and a structure of the fourth selection transistor T4 are at least partially symmetrical with respect to the second virtual straight line O2.

In an exemplary implementation, the demultiplexer provided in FIGS. 15 to 19 avoids the light shielding patterns of the selection transistors being in a floating state, which can reduce the influence of negative drift on the characteristics of the transistors, improve the signal transmission capability of the demultiplexer, and also form double gate structures with light shielding patterns and gate electrodes, improve the on-state current and mobility of the selection transistors, improve the reliability of the display product, and reduce a width of the demultiplexer, which is beneficial to the arrangement of the display substrate and increase a screen resolution of the display substrate.

In an exemplary implementation, in the demultiplexer provided in FIGS. 15 and 16, when the signal of the first selection signal line is an active level signal, the light shielding structure and the gate electrode of the first one of the first selection transistors, the light shielding structure and the gate electrode of the second one of the first selection transistors, and the light shielding structure and the gate electrode of the first selection transistor are respectively connected with the first selection signal line, so that the two first selection transistors and the third selection transistor are turned on, and the signal of the data output line is written to the first data signal line to which the distributor is connected. However, since the light shielding structure of the first one of the first selection transistors and the light shielding structure of the first one of the second selection transistors are integrated, when a signal written by the light shielding structure of the first one of the first selection transistors to the first selection signal line is an effective level signal, a signal written by the light shielding structure of the second one of the first selection transistors to the first selection signal line is also an effective level signal, and the first one of the second selection transistors may be turned on due to an existence of parasitic capacitance, so that the first data signal line to which the distributor is connected will also have output, resulting in false output. As compared with the demultiplexer provided in 15 and 16, the third selection transistor and the fourth selection transistor are added into the demultiplexer provided in FIGS. 17 and 18, so that when a signal of the first selection signal line is an effective level signal, the third selection transistor is turned on, the fourth selection transistor is turned off, and even if the first one of the second selection transistors is turned on, the signal is not output to the second data signal line to which the distributor is connected; and when a signal of the second selection signal line is an effective level signal, the fourth selection transistor is turned on, the third selection transistor is turned off, and even if the first one of the first selection transistors is turned on, the signal is not output to the first data signal line to which the distributor is connected. So, it can ensure the normal output of the demultiplexer, avoid false output, and improve the reliability of the demultiplexer.

In an exemplary implementation, as shown in conjunction with FIGS. 7, 8, 16, 18, and 19, when the light shielding patterns have single-layer structures, the display substrate includes: a light shielding layer, a semiconductor layer, a first conductive layer, and a second conductive layer sequentially stacked on the base substrate 10;
the light shielding layer includes at least: light shielding patterns of the selection transistors;
the semiconductor layer includes at least: active patterns of the selection transistors;
the first conductive layer includes at least gate electrodes of the selection transistors and the selection signal lines;
the second conductive layer includes at least the data signal lines, the data output lines, first electrodes and second electrodes of the selection transistors.

In an exemplary implementation, as shown in FIGS. 10, 11, 13, and 14, when the light shielding patterns have double-layer structures, the display substrate includes: a first light shielding layer, a second light shielding layer, a semiconductor layer, a first conductive layer, and a second conductive layer sequentially stacked on the base substrate 10;
the first light shielding layer includes at least: first light shielding patterns of the selection transistors;
the second light shielding layer includes at least: second light shielding patterns of the selection transistors;
the semiconductor layer includes at least: active patterns of the selection transistors;
the first conductive layer includes at least gate electrodes of the selection transistors and the selection signal lines;
the second conductive layer includes at least the data signal lines, the data output lines, first electrodes and second electrodes of the selection transistors.

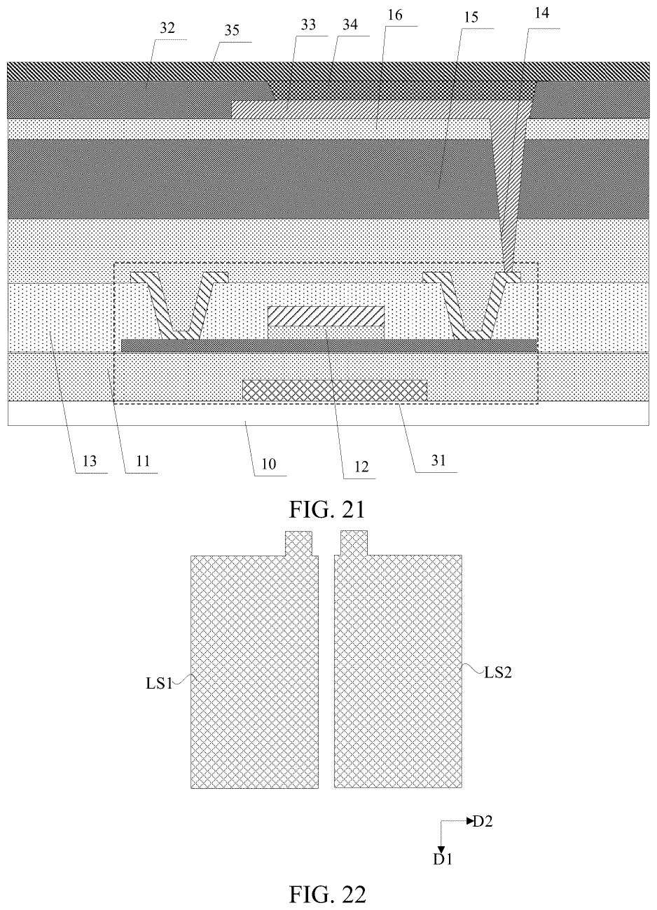

In an exemplary implementation, FIG. 20 is a first schematic diagram of a structure of a display area, and FIG. 21 is a second schematic diagram of a structure of a display area. As shown in FIGS. 8, 11, 14, 19, 20, and 21, the display substrate may further include a first insulation layer 11, a second insulation layer 12, a third insulation layer 13, a first planarization layer 14, a fourth insulation layer 15, and a second planarization layer 15. Herein, the first insulation layer 11 is located between the light shielding layer and the semiconductor layer, the second insulation layer 12 is located between the semiconductor layer and the first conductive layer, the third insulation layer 13 is located between the first conductive layer and the second conductive layer, and the first planarization layer 14, the fourth insulation layer 15, and the second planarization layer 15 are sequentially stacked on a side of the third insulation layer 13 away from the base substrate 10.

In an exemplary implementation, the first insulation layer 11 may have a single-layer structure or a multilayer structure. When the light shielding patterns have single-layer structures, the first insulation layer 11 has a single-layer structure. When the light shielding patterns have double-layer structures, the first insulation layer 11 has a double-layer structure, and at this time, the first insulation layer 11 may include a first sub-insulation layer 111 and a second sub-insulation layer 112, wherein the first sub-insulation layer 111 is located between the first light shielding layer and the second light shielding layer, and the second sub-insulation layer 112 is located between the second light shielding layer and the semiconductor layer.

In an exemplary implementation, the display substrate includes a drive structure layer. Herein, when the light shielding structures has single-layer structures, the drive structure layer includes the light shielding layer, the semiconductor layer, the first conductive layer, and the second conductive layer. When the light shielding structures have double-layer structures, the drive structure layer includes the first light shielding layer, the second light shielding layer, the semiconductor layer, the first conductive layer, and the second conductive layer.

In an exemplary implementation, as shown in FIG. 20, when the display substrate is an array substrate, the drive structure layer may further include the transistors 21, the pixel electrodes 22, and the common electrodes 23 located in the display area. Herein an orthographic projection of a pixel electrode 22 on the base substrate is at least partially overlapped with an orthographic projection of a common electrode 23 on the base substrate. The pixel electrode may be electrically connected with a transistor 21 and located on a side of the second planarization layer away from the base substrate, and the common electrode may be located between the fourth insulation layer and the second planarization layer. For example, gate electrodes of transistors located in the display area and gate electrodes of control transistors located in the non-display area are disposed on a same layer, active patterns of the transistors located in the display area and active patterns of the control transistors of the non-display area are disposed on a same layer, and first electrodes and second electrodes of the transistors located in the display area and first electrodes and second electrodes of the control transistors of the non-display area are disposed on a same layer.

In an exemplary implementation, as shown in FIG. 21, when the display substrate is an organic light emitting display substrate, the drive structure layer may further include drive circuits located in the display area, and the display substrate may further include a light emitting structure layer, and the light emitting structure layer includes light emitting devices. A drive circuit includes a plurality of transistors 31, and a light emitting device is electrically connected with the drive circuit, and is located on a side of the drive circuit away from the display area. The light emitting structure layer may include a pixel definition layer 32, first electrodes 33, an organic light emitting layer 34, and second electrodes 35. For example, gate electrodes of transistors located in the display area and gate electrodes of control transistors located in the non-display area are disposed on a same layer, active patterns of the transistors located in the display area and active patterns of the control transistors of the non-display area are disposed on a same layer, and first electrodes and second electrodes of the transistors located in the display area and first electrodes and second electrodes of the control transistors of the non-display area are disposed on a same layer.

In an exemplary implementation, the organic emitting layer may include a Hole Injection Layer (HIL), a Hole Transport Layer (HTL), an EMectron Block Layer (EBL), an Emitting Layer (EML), a Hole Block Layer (HBL), an EMectron Transport Layer (ETL), and an EMectron Injection Layer (EIL) that are stacked. In an exemplary implementation, hole injection layers of all sub-pixels may be connected together to be a common layer, electron injection layers of all the sub-pixels may be connected together to be a common layer, hole transport layers of all the sub-pixels may be connected together to be a common layer, electron transport layers of all the sub-pixels may be connected together to be a common layer, hole block layers of all the sub-pixels may be connected together to be a common layer, emitting layers of adjacent sub-pixels may be overlapped slightly or may be isolated, and electron block layers of adjacent sub-pixels may be overlapped slightly or may be isolated.

In an exemplary implementation, the display substrate may further include an encapsulation structure layer arranged on a side of the light emitting structure layer away from the base substrate. The display substrate may include another film layer such as a touch structure layer, which is not limited here in the present disclosure.

In an exemplary implementation, the encapsulation structure layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is disposed between the first encapsulation layer and the third encapsulation layer, which may be ensured that external moisture cannot enter the light emitting structure layer.

Exemplary description is made below through a manufacturing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition. The coating may be any one or more of spray coating, spin coating, and inkjet printing. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is located within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A is overlapped with the boundary of the orthographic projection of B.

The manufacturing process of the display substrate provided in FIGS. 7, 16, and 18, in which the light shielding patterns have single layer structures, will be illustrated below with one distributor. A manufacturing process of a display substrate according to an exemplary implementation may include following steps.

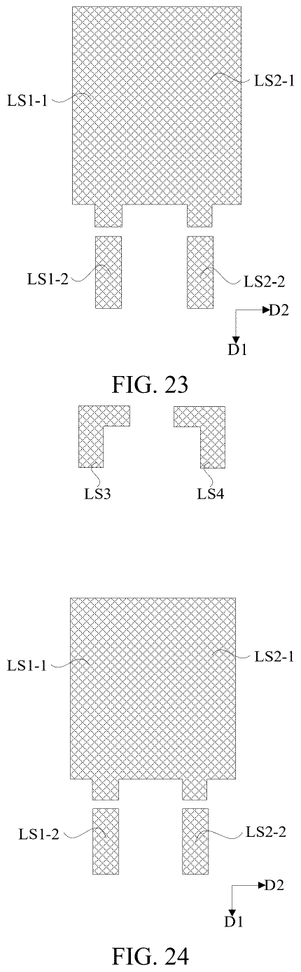

(1) Forming a pattern of a light shielding layer on a base substrate includes: depositing a light shielding thin film on the base substrate, patterning the light shielding thin film by a patterning process to form a pattern of a light shielding layer, as shown in 22 to 24. FIG. 22 is a schematic diagram of a pattern of a light shielding layer in FIG. 7, FIG. 23 is a schematic diagram of a pattern of a light shielding layer in FIG. 16, and FIG. 24 is a schematic diagram of a pattern of a light shielding layer in FIG. 18.

In an exemplary implementation, as shown in FIG. 22, the pattern of the light shielding layer may include at least a light shielding pattern LS1 of a first selection transistor and a light shielding pattern LS2 of a second selection transistor located in at least one distributor.

In an exemplary implementation, as shown in FIG. 22, the light shielding pattern LS1 of the first selection transistor and the light shielding pattern LS2 of the second selection transistor located in the same distributor are disposed separately and arranged in the second direction D2.

In an exemplary implementation, as shown in FIG. 22, a side of the light shielding pattern LS1 of the first selection transistor and the light shielding pattern LS2 of the second selection transistor close to the display area may be provided with a raised connection portion.

In an exemplary implementation, as shown in FIG. 22, a shape of the light shielding pattern LS1 of the first selection transistor may be a strip shape and may extend in the first direction D1. A shape of the light shielding pattern LS2 of the second selection transistor may be a strip shape, and may extend in the first direction D1.

In an exemplary implementation, as shown in FIG. 22, the light shielding pattern LS1 of the first selection transistor and the light shielding pattern LS2 of the second selection transistor may be symmetrical with respect to the first virtual straight line.

In an exemplary implementation, as shown in FIGS. 23 and 24, the pattern of the light shielding layer may include at least a light shielding pattern LS1-1 of a first one of the first selection transistors, a light shielding pattern LS1-2 of a second one of the first selection transistors, a light shielding pattern LS2-1 of a first one of the second selection transistors, and a light shielding pattern LS2-2 of a second one of the second selection transistors located in at least one distributor.

In an exemplary implementation, as shown in FIGS. 23 and 24, the light shielding pattern LS1-1 of the first one of the first selection transistors and the light shielding pattern LS2-1 of the first one of the second selection transistors located in the same distributor are formed into an integral structure. The light shielding pattern LS1-2 of the second one of the first selection transistors and the light shielding pattern LS2-2 of the second one of the second selection transistors are disposed separately and arranged in the second direction D2.

In an exemplary implementation, as shown in FIGS. 23 and 24, a shape of the light shielding pattern LS1-1 of the first one of the first selection transistors (also the light shielding pattern LS2-1 of the first one of the second selection transistors) may be block-shaped, and two raised connection portions are provided on a side of the light shielding pattern LS1-1 of the first one of the first selection transistors away from the non-display area.

In an exemplary implementation, as shown in FIGS. 23 and 24, the light shielding pattern LS1-2 of the second one of the first selection transistors and the light shielding pattern LS2-2 of the second one of the second selection transistors are located on a side of the raised connection portions away from the display area. The light shielding pattern LS1-2 of the second one of the first selection transistors and one of the raised connection portions are arranged in the first direction D1. The light shielding pattern LS2-2 of the second one of the second selection transistors and the other raised connection portion are arranged in the first direction D1.

In an exemplary implementation, as shown in FIGS. 23 and 24, shapes of the light shielding pattern LS1-2 of the second one of the first selection transistors and the light shielding pattern LS2-2 of the second one of the second selection transistors may be strip shapes and extend in the first direction D1.

In an exemplary implementation, as shown in FIGS. 23 and 24, the light shielding pattern LS1-1 of the first one of the first selection transistors (also the light shielding pattern LS2-1 of the first one of the second selection transistors) has an axisymmetric structure, and a symmetry axis extends in the first direction D1.

In an exemplary implementation, as shown in FIGS. 23 and 24, the light shielding pattern LS1-2 of the second one of the first selection transistors and the light shielding pattern LS2-2 of the second one of the second selection transistors may be symmetrical with respect to the second virtual straight line.

In an exemplary implementation, as shown in FIG. 24, the pattern of the light shielding layer may further include a light shielding pattern LS3 of a third selection transistor and a light shielding pattern LS4 of a fourth selection transistor located in at least one distributor.

In an exemplary implementation, as shown in FIG. 24, a light shielding pattern LS3 of a third selection transistor and a light shielding pattern LS4 of a fourth selection transistor located in a same distributor are disposed separately and arranged in the second direction D2. The light shielding pattern LS3 of the third selection transistor and the light shielding pattern LS4 of the fourth selection transistor are located on a side of the light shielding pattern LS1-1 of the first one of the first selection transistors (also the light shielding pattern LS2-1 of the first one of the second selection transistors) close to the display area.

In an exemplary implementation, as shown in FIG. 24, a shape of the light shielding pattern LS3 of the third selection transistor may be in a shape of a “┌”. A shape of the light shielding pattern LS 4 of the fourth selection transistor may be in a shape of a “┐”.

In an exemplary implementation, as shown in FIG. 24, the light shielding pattern LS3 of the third selection transistor and the light shielding pattern LS4 of the fourth selection transistor may be symmetrical with respect to the second virtual straight line.

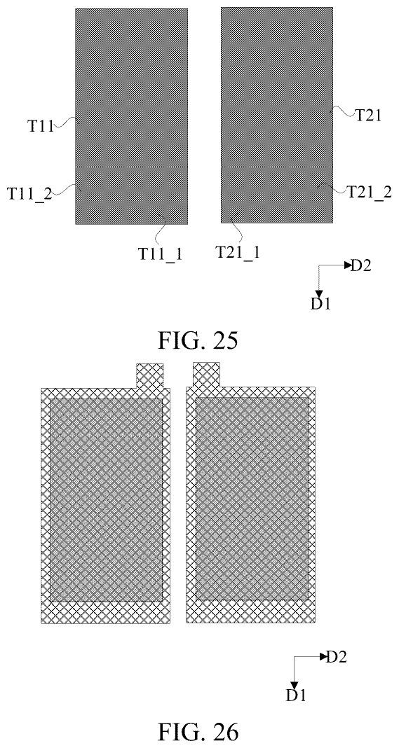

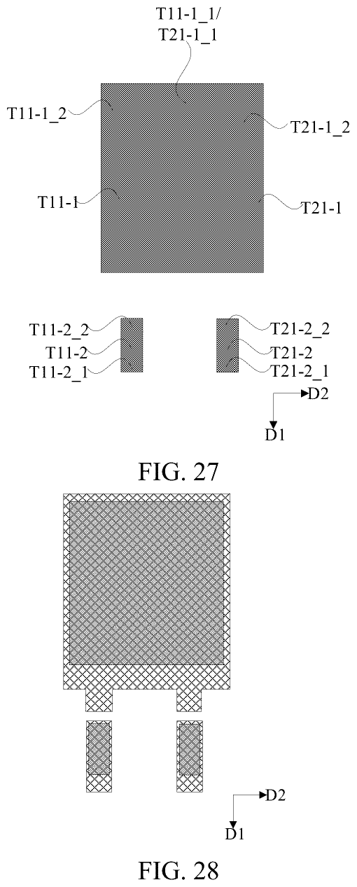

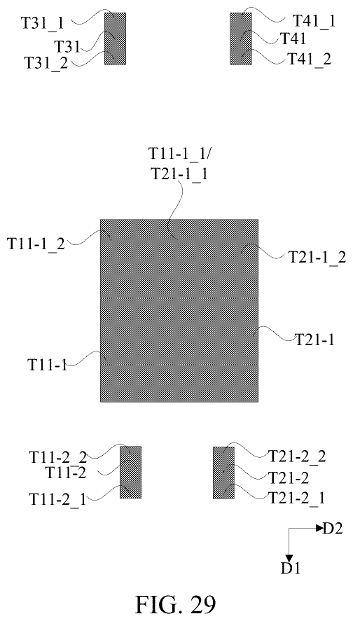

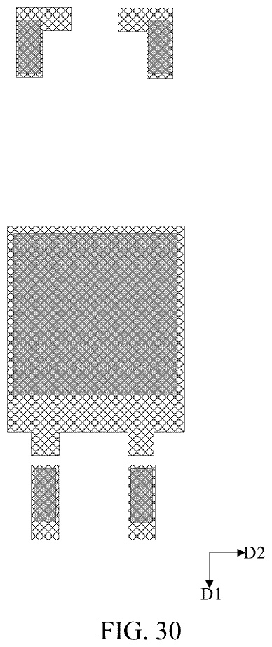

(2) Forming a pattern of a semiconductor layer. In an exemplary implementation, forming a pattern of a semiconductor layer may include sequentially depositing a first insulation thin film and a semiconductor thin film on the base substrate including the aforementioned pattern, patterning the semiconductor thin film by a patterning process to form a first insulation layer covering the light shielding layer and the pattern of the semiconductor layer located on the first insulation layer, as shown in FIGS. 25 to 30. FIG. 25 is a schematic diagram of a pattern of a semiconductor layer in FIG. 7, FIG. 26 is a schematic diagram after a pattern of a semiconductor layer is formed in FIG. 7, FIG. 27 is a schematic diagram a pattern of a semiconductor layer in FIG. 16, FIG. 28 is a schematic diagram after a pattern of a semiconductor layer is formed in FIG. 16, FIG. 29 is a schematic diagram a pattern of a semiconductor layer in FIG. 18, FIG. 30 is a schematic diagram after a pattern of a semiconductor layer is formed in FIG. 18.

In an exemplary implementation, as shown in FIGS. 25 and 26, the pattern of the semiconductor layer may include at least an active pattern T11 of a first selection transistor and an active pattern T21 of a second selection transistor located at least in a distributor.

In an exemplary implementation, as shown in FIGS. 25 and 26, the active pattern T11 of the first selection transistor and the active pattern T21 of the second selection transistor are disposed separately and arranged in the second direction D2.

In an exemplary implementation, as shown in FIGS. 25 and 26, shapes of the active pattern T11 of the first selection transistor and the active pattern T21 of the second selection transistor may be strip shapes and extend in the first direction D1.

In an exemplary implementation, as shown in FIGS. 25 and 26, the active pattern T11 of the first selection transistor and the active pattern T21 of the second selection transistor are symmetrical with respect to the first virtual straight line.

In an exemplary implementation, as shown in FIG. 26, an orthographic projection of a light shielding pattern of the first selection transistor on the base substrate covers an orthographic projection of the active pattern T11 of the first selection transistor on the base substrate. An orthographic projection of a light shielding pattern of the second selection transistor on the base substrate covers an orthographic projection of the active pattern T21 of the second selection transistor on the base substrate.

In an exemplary implementation, an active pattern of a transistor may include a first region, a second region, and a channel region located between the first region and the second region. As shown in FIGS. 25 and 26, a first region T11_1 of the active pattern T11 of the first selection transistor, a second region T11_2 of the active pattern T11 of the first selection transistor, a first region T21_1 of the active pattern T21 of the second selection transistor, and a second region T21_2 of the active pattern T21 of the second selection transistor are disposed separately.

In an exemplary implementation, as shown in FIGS. 27 to 30, the pattern of the semiconductor layer may include at least an active pattern T11-1 of a first one of the first selection transistors, an active pattern T11-2 of a second one of the first selection transistors, an active pattern T21-1 of a first one of the second selection transistors, and an active pattern T21-2 of a second one of the second selection transistors located at least in a distributor.

In an exemplary implementation, as shown in FIGS. 26 to 30, the active pattern T11-1 of the first one of the first selection transistors and the active pattern T21-1 of the first one of the second selection transistors are formed into an integral structure. The active pattern T11-2 of the second one of the first selection transistors and the active pattern T21-2 of the second one of the second selection transistors are disposed separately and arranged in the second direction D2.

In an exemplary implementation, as shown in FIGS. 26 to 30, a shape of the active pattern T11-1 of the first one of the first selection transistors (also the active pattern T21-1 of the first one of the second selection transistors) may be a strip shape and extend in the first direction D1. Shapes of the active pattern T11-2 of the second one of the first selection transistors and the active pattern T21-2 of the second one of the second selection transistors may be strip shapes and extend in the first direction D1.

In an exemplary implementation, as shown in FIGS. 26 to 30, the active pattern T11-1 of the first one of the first selection transistors (also the active pattern T21-1 of the first one of the second selection transistors) may have an axisymmetric structure, and a symmetry axis extends in the first direction D1. The active pattern T112 of the second one of the first selection transistors and the active pattern T21-2 of the second one of the second selection transistors are symmetrical with respect to the second virtual straight line.

In an exemplary implementation, as shown in FIGS. 26 to 30, an orthographic projection of a light shielding pattern of the first one of the first selection transistors (also the light shielding pattern of the first one of the second selection transistors) on the base substrate covers an orthographic projection of the active pattern T11-1 of the first one of the first selection transistors (also the active pattern T21-1 of the first one of the second selection transistors) on the base substrate. An orthographic projection of a light shielding pattern of the second one of the first selection transistors on the base substrate covers an orthographic projection of the active pattern T21-1 of the second one of the first selection transistors on the base substrate. An orthographic projection of a light shielding pattern of the second one of the second selection transistors on the base substrate covers an orthographic projection of the active pattern T21-2 of the second one of the second selection transistors on the base substrate.

In an exemplary implementation, an active pattern of a transistor may include a first region, a second region, and a channel region located between the first region and the second region. As shown in FIGS. 26 to 30, a first region T11-1_1 of the active pattern T11-1 of the first one of the first selection transistors and a first region T21-1_1 of the active pattern T21-1 of the first one of the second selection transistors are formed into an integral structure, and a second region T11-1_2 of the active pattern T11 of the first one of the first selection transistors, a second region T21-1_2 of the active pattern T21 of the first one of the second selection transistors, a first region T11-2_1 and a second region T11-2_2 of the active pattern T11-2 of the second one of the first selection transistors, and a first region T21-2_1 and a second region T21-2_2 of the active pattern T21-2 of the second one of the second selection transistors are disposed separately.

In an exemplary implementation, as shown in FIGS. 29 and 30, the pattern of the semiconductor layer may further include at least an active pattern T31 of the third selection transistor and an active pattern T41 of the fourth selection transistor located at least in a distributor.

In an exemplary implementation, as shown in FIGS. 29 and 30, the active pattern T31 of the third selection transistor and the active pattern T41 of the fourth selection transistor are disposed separately and arranged in the second direction D2.

In an exemplary implementation, as shown in FIGS. 29 and 30, shapes of the active pattern T31 of the third selection transistor and the active pattern T41 of the fourth selection transistor may be strip shapes and extend in the first direction D1.

In an exemplary implementation, as shown in FIGS. 29 and 30, the active pattern T31 of the third selection transistor and the active pattern T41 of the fourth selection transistor are symmetrical with respect to the second virtual straight line.

In an exemplary implementation, as shown in FIGS. 29 and 30, an orthographic projection of a light shielding pattern of the third selection transistor on the base substrate covers an orthographic projection of the active pattern T31 of the third selection transistor on the base substrate. An orthographic projection of a light shielding pattern of the fourth selection transistor on the base substrate covers an orthographic projection of the active pattern T41 of the fourth selection transistor on the base substrate.

In an exemplary implementation, an active pattern of a transistor may include a first region, a second region, and a channel region located between the first region and the second region. As shown in FIGS. 29 and 30, a first region T31_1 and a second region T31_2 of the active pattern T31 of the third selection transistor and a first region T41_1 and a second region T41_2 of the active pattern T41 of the fourth selection transistor are disposed separately.

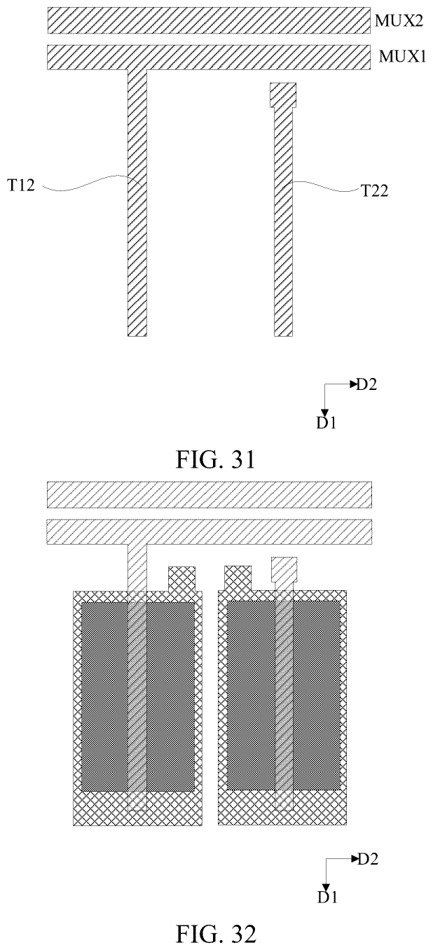

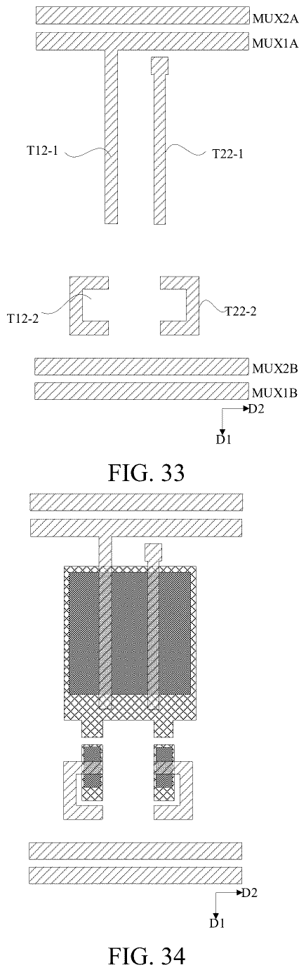

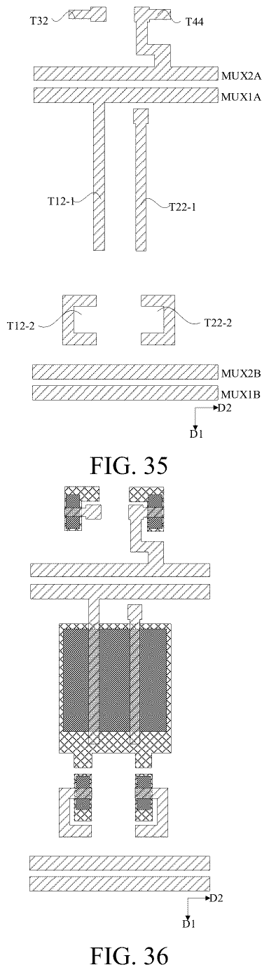

(3) Forming a pattern of a first conductive layer. In an exemplary implementation, forming a pattern of a first conductive layer may include sequentially depositing a second insulation thin film and a first conductive thin film on the base substrate on which the aforementioned patterns are formed, and patterning the first conductive thin film by a patterning process to form a second insulation layer covering the pattern of the semiconductor layer and the pattern of the first conductive layer located on the second insulation layer, as shown in FIG. 36. FIG. 31 is a schematic diagram of a pattern of a first conductive layer in FIG. 7, FIG. 32 is a schematic diagram after a pattern of a first conductive layer is formed in FIG. 7, FIG. 33 is a schematic diagram of a pattern of a first conductive layer in FIG. 16, FIG. 34 is a schematic diagram after a pattern of a first conductive layer is formed in FIG. 16, FIG. 35 is a schematic diagram of a pattern of a first conductive layer in FIG. 18, and FIG. 36 is a schematic diagram after a pattern of a first conductive layer is formed in FIG. 18. In an exemplary implementation, the first conductive layer may be referred to as a gate metal (Gate) layer.

In an exemplary implementation, as shown in FIGS. 31 and 32, the pattern of the first conductive layer may include at least a first selection signal line MUX1, a second selection signal line MUX2, and a gate electrode T12 of a first selection transistor and a gate electrode T22 of a second selection transistor located in at least one distributor.

In an exemplary implementation, as shown in FIGS. 31 and 32, the first selection signal line MUX1 and the gate electrode T12 of the first selection transistor are formed into an integral structure. The first selection signal line MUX 1 and the second selection signal line MUX 2 are located on a side of the distributor close to the display area. The gate electrode T12 of the first selection transistor and the gate electrode T22 of the second selection transistor are arranged in the second direction D2.

In an exemplary implementation, as shown in FIGS. 31 and 32, the first selection signal line MUX1 and the second selection signal line MUX2 extend in the second direction D2 and are arranged in the first direction D1.

In an exemplary implementation, as shown in FIGS. 31 and 32, shapes of the gate electrode T12 of the first selection transistor and the gate electrode T22 of the second selection transistor are strip shapes and extend in the first direction D1.

In an exemplary implementation, the first selection signal line MUX1 and the second selection signal line MUX2 may be in a design of equal width, or may be in a design of non-equal widths, may be straight lines, or may be polylines, which may not only facilitate a layout of a structure of a distributor, but also reduce the parasitic capacitance between the signal lines, which is not limited here in the present disclosure.

In an exemplary implementation, the gate electrode T12 of the first selection transistor is disposed across an active pattern of the first selection transistor, and the gate electrode T22 of the second selection transistor is disposed across an active pattern of the second selection transistor, that is, an extension direction of a gate electrode of at least one transistor and an extension direction of an active pattern of the at least one transistor are perpendicular to each other.

In an exemplary implementation, after the pattern of the first conductive layer is formed, a conductive treatment may be performed on the semiconductor layer by using the first conductive layer as a shield. Regions of the semiconductor layer, which are shielded by the first conductive layer, form channel regions of the first selection transistor and the second selection transistor, and regions of the semiconductor layer, which are not shielded by the first conductive layer, are made to be conductive, that is, a first region and a second region of an active pattern of any one of the first selection transistor and the second selection transistor are all made to be conductive.

In an exemplary implementation, as shown in FIGS. 33 to 36, the pattern of the first conductive layer may include at least a first sub-selection signal line MUX1A and a second sub-selection signal line MUX1B of a first selection signal line, a first sub-selection signal line MUX2A and a second sub-selection signal line MUX2B of a second selection signal line, and a gate electrode T12-1 of a first one of the first selection transistors, a gate electrode T12-2 of a second one of the first selection transistors, a gate electrode T22-1 of a first one of the second selection transistors, a gate electrode T22-2 of a second one of the second selection transistors, which are located in at least one distributor.

In an exemplary implementation, as shown in FIGS. 33 to 36, the first sub-selection signal line MUX1A of the first selection signal line and the gate electrode T12-1 of the first one of the first selection transistors are formed into an integral structure. The second sub-selection signal line MUX1B of the first selection signal line, the first sub-selection signal line MUX2A and the second sub-selection signal line MUX2B of the second selection signal line, the gate electrode T12-2 of the second one of the first selection transistors, the gate electrode T22-1 of the first one of the second selection transistors, and the gate electrode T22-2 of the second one of the second selection transistors are disposed separately.

In an exemplary implementation, as shown in FIGS. 33 to 36, the gate electrode T12-1 of the first one of the first selection transistors and the gate electrode T22-1 of the first one of the second selection transistors are arranged in the second direction D2. The gate electrode T12-2 of the second one of the first selection transistors and the gate electrode T22-2 of the second one of the second selection transistors are arranged in the second direction D2. The gate electrode T12-1 of the first one of the first selection transistors and the gate electrode T22-1 of the first one of the second selection transistors are located on a side of the gate electrode T12-2 of the second one of the first selection transistors and the gate electrode T22-2 of the second one of the second selection transistors close to the display area, the first sub-selection signal line MUX1A of the first selection signal line and the first sub-selection signal line MUX2A of the second selection signal line are located on a side of the gate electrode T22-1 of the first one of the second selection transistors close to the display area, and the second sub-selection signal line MUX1B of the first selection signal line and the second sub-selection signal line MUX2B of the second selection signal line are located on a side of the gate electrode T22-2 of the second one of the second selection transistors away from the display area.

In an exemplary implementation, as shown in FIGS. 33 to 36, shapes of the first sub-selection signal line MUX1A and the second sub-selection signal line MUX1B of the first selection signal line, and the second sub-selection signal line MUX2B of the second selection signal line are line shapes and extend in the second direction D2.

In an exemplary implementation, as shown in FIGS. 33 and 34, a shape of the first sub-selection signal line MUX2A of the second selection signal line is a line shape and extends in the second direction D2 In an exemplary implementation, as shown in FIGS. 35 and 36, the first sub-selection signal line MUX2A of the second selection signal line includes a main body portion extending in the second direction D2 and a signal connection portion. A shape of the main body portion is a straight line shape and extends in the second direction D2, and the signal connection portion is located on a side of the main body portion close to the display area, and has a polyline shape.

In an exemplary implementation, as shown in FIGS. 33 to 36, shapes of the gate electrode T12-1 of the first one of the first selection transistors and the gate electrode T22-1 of the first one of the second selection transistors are strip shapes and extend in the first direction D1.

In an exemplary implementation, as shown in FIGS. 33 to 36, shapes of the gate electrode T12-2 of the second one of the first selection transistors and the gate electrode T22-2 of the second one of the second selection transistors are groove-shaped, and an opening of the gate electrode T12-2 of the second one of the first selection transistors faces the gate electrode T22-2 of the second one of the second selection transistors, and an opening of a groove of the gate electrode T22-2 of the second one of the second selection transistors faces the gate electrode T12-2 of the second one of the first selection transistors.

In an exemplary implementation, as shown in FIGS. 33 and 36, the gate electrode T12-2 of the second one of the first selection transistors and the gate electrode T22-2 of the second one of the second selection transistors are symmetrical with respect to the second virtual straight line.

In an exemplary implementation, the first sub-selection signal line MUX1A and the second sub-selection signal line MUX1B of the first selection signal line, and the first sub-selection signal line MUX2A and the second sub-selection signal line MUX2B of the second selection signal line may be in a design of equal width, or may be in a design of non-equal widths, may be straight lines, or may be polylines, which may not only facilitate the layout of the structure of the distributor, but also reduce the parasitic capacitance between the signal lines, which is not limited here in the present disclosure.

In an exemplary implementation, the gate electrode T12-1 of the first one of the first selection transistors is disposed across the active pattern of the first one of the first selection transistors, the gate electrode T12-2 of the second one of the first selection transistors is disposed across the active pattern of the first one of the first selection transistors, the gate electrode T22-1 of the first one of the second selection transistors is disposed across the active pattern of the first one of the second selection transistors, and the gate electrode T22-2 of the second selection transistor is disposed across the active pattern of the second one of the second selection transistors, that is, extension directions of a gate electrode and an active pattern of at least one transistor are perpendicular to each other.

In an exemplary implementation, after the pattern of the first conductive layer is formed, a conductive treatment may be performed on the semiconductor layer by using the first conductive layer as a shield. A region of the semiconductor layer, which is shielded by the first conductive layer, forms channel regions of the first selection transistor and the second selection transistor, and a region of the semiconductor layer, which is not shielded by the first conductive layer, is made to be conductive, that is, a first region and a second region of an active pattern of any one of the first one of the first selection transistors, the second one of the first selection transistors, the first one of the second selection transistors, and the second selection transistor are all made to be conductive.

In an exemplary implementation, as shown in FIGS. 35 and 36, the pattern of the first conductive layer may further include a gate electrode T32 of a third selection transistor and a gate electrode T42 of a fourth selection transistor located in at least one distributor.

In an exemplary implementation, as shown in FIGS. 35 and 36, the gate electrode T42 of the fourth selection transistor and the first sub-selection signal line MUX2A of the second selection signal line are formed into an integral structure. The gate electrode T32 of the third selection transistor is disposed separately, and the gate electrode T32 of the third selection transistor and the gate electrode T42 of the fourth selection transistor are arranged in the second direction D2.

In an exemplary implementation, as shown in FIGS. 35 and 36, the gate electrode T32 of the third selection transistor and the gate electrode T42 of the fourth selection transistor are located on a side of the first sub-selection signal line MUX2A of the second selection signal line close to the display area.

In an exemplary implementation, as shown in FIGS. 35 and 36, the gate electrode T42 of the fourth selection transistor is connected with the signal connection portion of the first sub-selection signal line MUX2A of the second selection signal line.

In an exemplary implementation, as shown in FIGS. 35 and 36, shapes of the gate electrode T32 of the third selection transistor and the gate electrode T42 of the fourth selection transistor are strip shapes and extend in the second direction D2.

In an exemplary implementation, as shown in FIGS. 35 and 36, the gate electrode T32 of the third selection transistor and the gate electrode T42 of the fourth selection transistor are symmetrical with respect to the second virtual straight line.

In an exemplary implementation, the gate electrode T32 of the third selection transistor is disposed across an active pattern of the third selection transistor, and the gate electrode T42 of the fourth selection transistor is disposed across an active pattern of the fourth selection transistor.

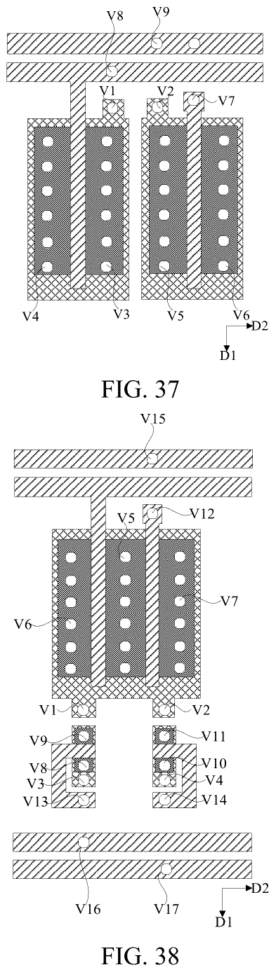

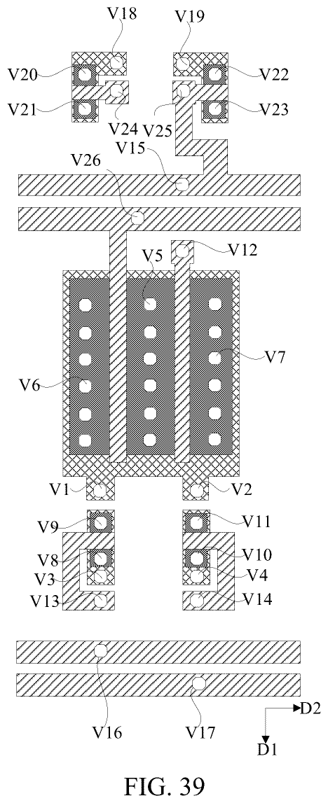

(4) Forming a pattern of a third insulation layer. In an exemplary implementation, forming a pattern of the third insulation layer may include: depositing a third insulation thin film on the base substrate on which the aforementioned patterns are formed, patterning the third insulation thin film by a patterning process, to form a third insulation layer covering the first conductive layer, and providing a plurality of vias on the third insulation layer, as shown in FIGS. 37 to 39. FIG. 37 is a schematic diagram of a pattern of a third insulation layer pattern in FIG. 7, FIG. 38 is a schematic diagram of a pattern of a third insulation layer in FIG. 16, and FIG. 39 is a schematic diagram of a pattern of a third insulation layer in FIG. 18.

In an exemplary implementation, as shown in FIG. 37, the plurality of vias of the third insulation layer may include at least a first via V1 to ninth vias V9 located in at least one distributor.

In an exemplary implementation, as shown in FIG. 37, an orthographic projection of the first via V1 on the base substrate is within a range of an orthographic projection of a light shielding pattern of the first selection transistor on the base substrate, the first insulation layer and the second insulation layer within the first via VI are etched away to expose a surface of the light shielding pattern of the first selection transistor, and the first via V1 is configured to connect a first connection line to be formed subsequently with the light shielding pattern of the first selection transistor through this via.

In an exemplary implementation, as shown in FIG. 37, an orthographic projection of a second via V2 on the base substrate is within a range of an orthographic projection of a light shielding pattern of the second selection transistor on the base substrate, the first insulation layer and the second insulation layer within the second via V2 are etched away to expose a surface of the light shielding pattern of the second selection transistor, and the second via V2 is configured to connect a second connection line to be formed subsequently with the light shielding pattern of the second selection transistor through this via.

In an exemplary implementation, as shown in FIG. 37, orthographic projections of third vias V3 on the base substrate are located within a range of an orthographic projection of a first region of an active pattern of the first selection transistor on the base substrate, the second insulation layer within the third vias V3 is etched away to expose a surface of the first region of the active pattern of the first selection transistor, and the third vias V3 are configured to connect a first electrode of the first selection transistor (also a first electrode of the second selection transistor) to be formed subsequently with the first region of the active pattern of the first selection transistor through these vias.

In an exemplary implementation, as shown in FIG. 37, orthographic projections of fourth vias V4 on the base substrate is within a range of an orthographic projection of a second region of the active pattern of the first selection transistor on the base substrate, the second insulation layer within the fourth vias V4 is etched away to expose a surface of the second region of the active pattern of the first selection transistor, and the fourth vias V4 are configured to connect a second electrode of the first selection transistor to be formed subsequently with the second region of the active pattern of the first selection transistor through these vias.

In an exemplary implementation, as shown in FIG. 37, orthographic projections of fifth vias V5 on the base substrate are located within a range of an orthographic projection of a first region of an active pattern of the second selection transistor on the base substrate, the second insulation layer within the fifth vias V5 is etched away to expose a surface of the first region of the active pattern of the second selection transistor, and the fifth vias V5 are configured to connect the first electrode of the first selection transistor (also the first electrode of the second selection transistor) to be formed subsequently with the first region of the active pattern of the second selection transistor through these vias.

In an exemplary implementation, as shown in FIG. 37, orthographic projections of sixth vias V6 on the base substrate are located within a range of an orthographic projection of a second region of the active pattern of the second selection transistor on the base substrate, the second insulation layer within the sixth vias V6 is etched away to expose a surface of the second region of the active pattern of the second selection transistor, and the sixth vias V6 are configured to connect a second electrode of the second selection transistor to be formed subsequently with the second region of the active pattern of the second selection transistor through these vias.

In an exemplary implementation, as shown in FIG. 37, an orthographic projection of the seventh via V7 on the base substrate is within a range of an orthographic projection of a gate electrode of the second selection transistor on the base substrate, the seventh via V7 exposes a surface of the gate electrode of the second selection transistor, and the seventh via V7 is configured to connect a third connection line to be formed subsequently with the gate electrode of the second selection transistor through this via.

In an exemplary implementation, as shown in FIG. 37, an orthographic projection of an eighth via V8 on the base substrate is within a range of an orthographic projection of the first selection signal line on the base substrate, the eighth via V8 exposes a surface of the first selection signal line, and the eighth via V8 is configured to connect the first connect line to be formed subsequently with the first selection signal line through this via.

In an exemplary implementation, as shown in FIG. 37, orthographic projections of the ninth vias V9 on the base substrate are located within a range of an orthographic projection of the second selection signal line on the base substrate, the ninth vias V9 expose a surface of the second selection signal line, and the ninth vias V9 are configured to connect the second connection line and the third connection line to be formed subsequently with the second selection signal line through these vias.

In an exemplary implementation, as shown in FIG. 37, a quantity of any one of the third vias V3, the fourth vias V4, the fifth vias V5, and the sixth vias V6 is at least one, for example, may be one, or may be multiple, and any one of the third vias V3, the fourth vias V4, the fifth vias V5, and the sixth vias V6 are arranged in the first direction D1. FIG. 37 is illustrated by taking an example in which the quantity of any one of the third vias V3, the fourth vias V4, the fifth vias V5, and the sixth vias V6 is multiple.

In an exemplary implementation, as shown in FIG. 38, the plurality of vias of the third insulation layer may include at least a first via V1 to a seventeenth via V17 located in at least one distributor.

In an exemplary implementation, as shown in FIG. 39, the plurality of vias of the third insulation layer may include at least a first via V1 to a twenty-sixth via V26 located in at least one distributor.

In an exemplary implementation, as shown in FIGS. 38 and 39, an orthographic projection of a first via V1 on the base substrate is within a range of an orthographic projection of a light shielding pattern of a first one of the first selection transistors on the base substrate, the first insulation layer and the second insulation layer within the first via VI are etched away to expose the surface of the light shielding pattern of the first one of the first selection transistors, and the first via V1 is configured to connect a second electrode of a second one of the first selection transistors to be formed subsequently with the light shielding pattern of the first one of the first selection transistors through this via.

In an exemplary implementation, as shown in FIGS. 38 and 39, an orthographic projection of a second via V2 on the base substrate is within a range of an orthographic projection of a light shielding pattern of a first one of the second selection transistors on the base substrate, the first insulation layer and the second insulation layer within the second via V2 are etched away to expose a surface of the light shielding pattern of the first one of the second selection transistors, and the second via V2 is configured to connect a second electrode of a second one of the second selection transistors to be formed subsequently with the light shielding pattern of the first one of the second selection transistors through this via.

In an exemplary implementation, as shown in FIGS. 38 and 39, an orthographic projection of a third via V3 on the base substrate is within a range of an orthographic projection of a light shielding pattern of a second one of the first selection transistors on the base substrate, the first insulation layer and the second insulation layer within the third via V3 are etched away to expose a surface of the light shielding pattern of the second one of the first selection transistors, and the third via V3 is configured to connect a first electrode of the second one of the first selection transistors to be formed subsequently with the light shielding pattern of the second one of the first selection transistors through this via.

In an exemplary implementation, as shown in FIGS. 38 and 39, an orthographic projection of a fourth via V4 on the base substrate is within a range of an orthographic projection of a light shielding pattern of the second one of the second selection transistors on the base substrate, the first insulation layer and the second insulation layer within the fourth via V4 are etched away to expose a surface of the light shielding pattern of the second one of the second selection transistors, and the fourth via V4 is configured to connect a first electrode of the second one of the second selection transistors to be formed subsequently with the light shielding pattern of the second one of the second selection transistors through this via.

In an exemplary implementation, as shown in FIG. 37, orthographic projections of fifth vias V5 on the base substrate are within a range of an orthographic projection of a first region of an active pattern of the first one of the first selection transistors (also a first region of an active pattern of the first one of the second selection transistors) on the base substrate, the second insulation layer within the fifth vias V5 is etched away, to expose a surface of the first region of the active pattern of the first one of the first selection transistors (also the first region of the active pattern of the first one of the second selection transistors), the fifth vias V5 are configured to connect a first electrode of the first one of the first selection transistors (also a first electrode of the first one of the second selection transistors) to be formed subsequently with the first region of the active pattern of the first one of the first selection transistors (also the first region of the active pattern of the first one of the second selection transistors) through these vias.

In an exemplary implementation, as shown in FIGS. 38 and 39, orthographic projections of sixth vias V6 on the base substrate is within a range of an orthographic projection of a second region of the active pattern of the first one of the first selection transistors on the base substrate, the second insulation layer within the sixth vias V6 is etched away, to expose a surface of the second region of the active pattern of the first one of the first selection transistors, and the sixth vias V6 is configured to connect a second electrode of the first one of the first selection transistors to be formed subsequently with the second region of the active pattern of the first one of the first selection transistors through these via.

In an exemplary implementation, as shown in FIGS. 38 and 39, orthographic projections of seventh vias V7 on the base substrate are within a range of an orthographic projection of a second region of the active pattern of the first one of the second selection transistors on the base substrate, the second insulation layer within the seventh via V7 is etched away to expose a surface of the second region of the active pattern of the first one of the second selection transistors, and the seventh via V7 is configured to connect a second electrode of the first one of the second selection transistors to be formed subsequently with the second region of the active pattern of the first one of the second selection transistors through these vias.

In an exemplary implementation, as shown in FIGS. 38 and 39, an orthographic projection of an eighth via V8 on the base substrate is within a range of an orthographic projection of a first region of an active pattern of the second one of the first selection transistors on the base substrate, the second insulation layer within the eighth via V8 is etched away to expose a surface of the first region of the active pattern of the second one of the first selection transistors, and the eighth via V8 is configured to connect the first electrode of the second one of the first selection transistors to be formed subsequently with the first region of the active pattern of the second one of the first selection transistors through this via.

In an exemplary implementation, as shown in FIGS. 38 and 39, an orthographic projection of a ninth via V9 on the base substrate is within a range of an orthographic projection of a second region of the active pattern of the second one of the first selection transistors on the base substrate, the second insulation layer within the ninth via V9 is etched away to expose a surface of the second region of the active pattern of the second one of the first selection transistors, and the ninth via V9 is configured to connect a second electrode of the second one of the first selection transistors to be formed subsequently with the second region of the active pattern of the second one of the first selection transistors through this via.

In an exemplary implementation, as shown in FIGS. 38 and 39, an orthographic projection of a tenth via V10 on the base substrate is located within a range of an orthographic projection of a first region of an active pattern of the second one of the second selection transistors on the base substrate, the second insulation layer within the tenth via V10 is etched away to expose a surface of the first region of the active pattern of the second one of the second selection transistors, and the tenth via V10 is configured to connect a first electrode of the second one of the second selection transistors to be formed subsequently with the first region of the active pattern of the second one of the second selection transistors through this via.

In an exemplary implementation, as shown in FIGS. 38 and 39, an orthographic projection of an eleventh via V11 on the base substrate is within a range of an orthographic projection of a second region of the active pattern of the second one of the second selection transistors on the base substrate, the second insulation layer within the eleventh via V11 is etched away to expose a surface of the second region of the active pattern of the second one of the second selection transistors, and the eleventh via V11 is configured to connect a second electrode of the second one of the second selection transistors to be formed subsequently with the second region of the active pattern of the second one of the second selection transistors through this via.

In an exemplary implementation, as shown in FIGS. 38 and 39, an orthographic projection of a twelfth via V12 on the base substrate is within a range of an orthographic projection of a gate electrode of the first one of the second selection transistors on the base substrate, the twelfth via V12 exposes a surface of the gate electrode of the first one of the second selection transistors, and the twelfth via V12 is configured to connect a fourth connection line to be formed subsequently with the gate electrode of the first one of the second selection transistors through this via.

In an exemplary implementation, as shown in FIGS. 38 and 39, an orthographic projection of a thirteenth via V13 on the base substrate is within a range of an orthographic projection of a gate electrode of the second one of the first selection transistors on the base substrate, the thirteenth via V13 exposes a surface of the gate electrode of the second one of the first selection transistors, and the thirteenth via V13 is configured to connect a first electrode of the second one of the first selection transistors to be formed subsequently with the gate electrode of the second one of the first selection transistors through this via.

In an exemplary implementation, as shown in FIGS. 38 and 39, an orthographic projection of a fourteenth via V14 on the base substrate is within a range of an orthographic projection of a gate electrode of the second one of the second selection transistors on the base substrate, the fourteenth via V14 exposes a surface of the gate electrode of the second one of the second selection transistors, and the fourteenth via V14 is configured to connect a first electrode of the second one of the second selection transistors to be formed subsequently with the gate electrode of the second one of the second selection transistors through this via.

In an exemplary implementation, as shown in FIGS. 38 and 39, an orthographic projection of a fifteenth via V15 on the base substrate is located within a range of an orthographic projection of a first sub-selection signal line of a second selection signal line on the base substrate, the fifteenth via V15 exposes a surface of the first sub-selection signal line of the second selection signal line, and the fifteenth via V15 is configured to connect the fourth connection line to be formed subsequently with the first sub-selection signal line of the second selection signal line through this via.

In an exemplary implementation, as shown in FIGS. 38 and 39, an orthographic projection of a sixteenth via V16 on the base substrate is within a range of an orthographic projection of a second sub-selection signal line of a first selection signal line on the base substrate, the sixteenth via V16 exposes a surface of the second sub-selection signal line of the first selection signal line, and the sixteenth via V16 is configured to connect a first electrode of the second one of the first selection transistors to be formed subsequently with the second sub-selection signal line of the first selection signal line through this via.

In an exemplary implementation, as shown in FIGS. 38 and 39, an orthographic projection of a seventeenth via V17 on the base substrate is within a range of an orthographic projection of a second sub-selection signal line of a second selection signal line on the base substrate, the seventeenth via V17 exposes a surface of the second sub-selection signal line of the second selection signal line, and the seventeenth via V17 is configured to connect the first electrode of the second one of the second selection transistors to be formed subsequently with the second sub-selection signal line of the second selection signal line through this via.

In an exemplary implementation, as shown in FIG. 39, an orthographic projection of an eighteenth via V18 on the base substrate is within a range of an orthographic projection of the light shielding pattern of the third selection transistor on the base substrate, the first insulation layer and the second insulation layer within the eighteenth via V18 are etched away to expose a surface of the light shielding pattern of the third selection transistor, and the eighteenth via V18 is configured to connect a fifth connection line to be formed subsequently with the light shielding pattern of the third selection transistor through this via.

In an exemplary implementation, as shown in FIG. 39, an orthographic projection of a nineteenth via V19 on the base substrate is within a range of an orthographic projection of the light shielding pattern of the fourth selection transistor on the base substrate, the first insulation layer and the second insulation layer within the nineteenth via V19 are etched away to expose a surface of the light shielding pattern of the fourth selection transistor, and the nineteenth via V19 is configured to connect a sixth connection line to be formed subsequently with the light shielding pattern of the fourth selection transistor through this via.

In an exemplary implementation, as shown in FIG. 39, an orthographic projection of a twentieth via V20 on the base substrate is within a range of an orthographic projection of a first region of an active pattern of the third selection transistor on the base substrate, the second insulation layer within the twentieth via V20 is etched away to expose a surface of the first region of the active pattern of the third selection transistor, and the twentieth via V20 is configured to connect a first electrode of the third selection transistor to be formed subsequently with the first region of the active pattern of the third selection transistor through this via.

In an exemplary implementation, as shown in FIG. 39, an orthographic projection of a twenty-first via V21 on the base substrate is located within a range of an orthographic projection of a second region of the active pattern of the third selection transistor on the base substrate, the second insulation layer within the twenty-first via V21 is etched away to expose a surface of the second region of the active pattern of the third selection transistor, and the twenty-first via V21 is configured connect the second electrode of the first one of the first selection transistors (also a second electrode of the third selection transistor) to be formed subsequently with the second region of the active pattern of the third selection transistor through this via.

In an exemplary implementation, as shown in FIG. 39, an orthographic projection of a twenty-second via V22 on the base substrate is within a range of an orthographic projection of a first region of the active pattern of the fourth selection transistor on the base substrate, the second insulation layer within the twenty-second via V22 is etched away to expose a surface of the first region of the active pattern of the fourth selection transistor, and the twenty-second via V22 is configured to connect a first electrode of the fourth selection transistor to be formed subsequently with the first region of the active pattern of the fourth selection transistor through this via.

In an exemplary implementation, as shown in FIG. 39, an orthographic projection of a twenty-third via V23 on the base substrate is located within a range of an orthographic projection of a second region of the active pattern of the fourth selection transistor on the base substrate, the second insulation layer within the twenty-third via V23 is etched away to expose a surface of the second region of the active pattern of the fourth selection transistor, and the twenty-third via V23 is configured to connect a second electrode of the first one of the second selection transistors (also a second electrode of the fourth selection transistor) to be formed subsequently with the second region of the active pattern of the fourth selection transistor through this via.

In an exemplary implementation, as shown in FIG. 39, an orthographic projection of a twenty-fourth via V24 on the base substrate is within a range of an orthographic projection of a gate electrode of the third selection transistor on the base substrate, the twenty-fourth via V24 exposes a surface of the gate electrode of the third selection transistor, and the twenty-fourth via V24 is configured to connect a fifth connection line to be formed subsequently with the gate electrode of the third selection transistor through this via.

In an exemplary implementation, as shown in FIG. 39, an orthographic projection of a twenty-fifth via V25 on the base substrate is within a range of an orthographic projection of a gate electrode of the fourth selection transistor on the base substrate, the twenty-fifth via V25 exposes a surface of the gate electrode of the fourth selection transistor, and the twenty-fifth via V25 is configured to connect a sixth connection line to be formed subsequently with the gate electrode of the fourth selection transistor through this via.

In an exemplary implementation, as shown in FIG. 39, an orthographic projection of a twenty-sixth via V26 on the base substrate is within a range of an orthographic projection of a first sub-selection signal line of the first selection signal line on the base substrate, the twenty-sixth via V26 exposes a surface of the first sub-selection signal line of the first selection signal line, and the twenty-sixth via V26 is configured to connect the fifth connection line to be formed subsequently with the first sub-selection signal line of the first selection signal line through this via.

In an exemplary implementation, as shown in FIGS. 38 and 39, a quantity of any one of the fifth vias V5, the sixth vias V6, and the seventh vias V7 is at least one, for example, the quantity of any one of the fifth vias V5, the sixth vias V6, and the seventh vias V7 may be one, or may be multiple, and any one of the fifth vias V5, the sixth vias V6, and the seventh vias V7 may be arranged in the first direction D1, and FIGS. 38 and 39 are illustrated by taking an example in which the quantity of any one of the fifth vias V5, the sixth vias V6, and the seventh vias V7 is multiple.

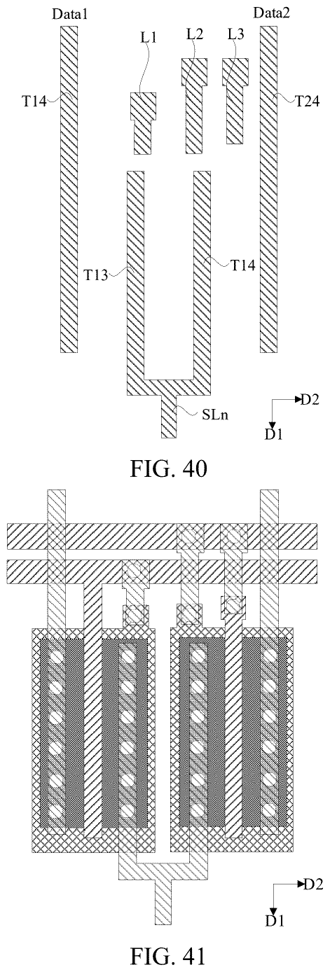

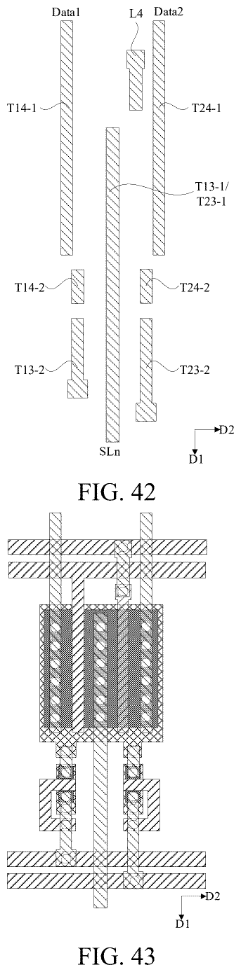

(5) Forming a pattern of a second conductive layer. In an exemplary implementation, forming a pattern of a second conductive layer may include: depositing a second conductive thin film on the base substrate on which the aforementioned patterns are formed, patterning the second conductive thin film by a patterning process to form the pattern of the second conductive layer disposed on the third insulation layer, as shown in FIGS. 40 to 45. FIG. 40 is a schematic diagram of a pattern of a second conductive layer in FIG. 7, FIG. 41 is a schematic diagram after a pattern of a second conductive layer is formed in FIG. 7, FIG. 42 is a schematic diagram of a pattern of a second conductive layer in FIG. 16, FIG. 43 is a schematic diagram after a pattern of a second conductive layer is formed in FIG. 16, FIG. 44 is a schematic diagram of a pattern of a second conductive layer in FIG. 18, and FIG. 45 is a schematic diagram after a pattern of a second conductive layer is formed in FIG. 18. In an exemplary implementation, the second conductive layer may be referred to as a Source Drain metal (SD) layer.

In an exemplary implementation, as shown in FIGS. 40 and 41, the pattern of the second conductive layer may include at least a first data signal line Data1, a second data signal line Data2, and a data output line SLn to which the distributor is connected, and a first electrode T13 and a second electrode T14 of a first selection transistor, a first electrode T23 and a second electrode T24 of a second selection transistor, a first connection line L1, a second connection line L2, and a third connection line L3 located in at least one distributor.

In an exemplary implementation, the first data signal line Data1, the second data signal line Data2, and the data output line SLn to which the distributor is connected extend in the first direction D1.

In an exemplary implementation, as shown in FIGS. 40 and 41, the first electrode T13 of the first selection transistor, the first electrode T23 of the second selection transistor, and the data output line SLn are formed into an integral structure, the second electrode T14 of the first selection transistor and the first data signal line Data1 to which the distributor is connected are formed into an integral structure, and the second electrode T24 of the second selection transistor and the second data signal line Data2 to which the distributor is connected are formed into an integral structure.

In an exemplary implementation, shapes of the first electrode T13 of the first selection transistor and the first electrode T23 of the second selection second selection transistor are groove shapes in which openings face the display area. The first electrode T13 of the first selection transistor (also the first electrode T23 of the second selection transistor) is connected with a first region of an active pattern of the first selection transistor through a third via, and is connected with a first region of an active pattern of the second selection transistor through a fifth via.

In an exemplary implementation, the second electrode T14 of the first selection transistor is connected with the second region of the active pattern of the first selection transistor through a fourth via. The second electrode T24 of the second selection transistor is connected with a second region of the active pattern of the second selection transistor through a sixth via.

In an exemplary implementation, a shape of a first connection line L1 is a strip shape and extends in the first direction D1. The first connection line L1 is connected with a light shielding pattern of the first selection transistor through a first via, and is connected with the first selection signal line through an eighth via.

In an exemplary implementation, the shape of a second connection line L2 is a strip shape and extends in the first direction D1. The second connection line L2 is connected with a light shielding pattern of the second selection transistor through a second via, and is connected with the second selection signal line through a ninth via.

In an exemplary implementation, a shape of a third connection line L3 is a strip shape and extends in the first direction D1. The third connection line L3 is connected with a gate electrode of the second selection transistor through a seventh via, and is connected with the second selection signal line through the ninth via.

In an exemplary implementation, as shown in FIGS. 42 to 45, the pattern of the second conductive layer may include at least a first data signal line Data1, a second data signal line Data2, and a data output line SLn to which the distributor is connected, and a first electrode T13-1 and a second electrode T14-1 of a first one of the first selection transistors, a first electrode T13-2 and a second electrode T14-2 of a second one of the first selection transistors, a first electrode T23-1 and a second electrode T24-1 of a first one of the second selection transistors, a first electrode T23-2 and a second electrode T24-2 of a second one of the second selection transistors, and a fourth connection line L4 located in at least one distributor.

In an exemplary implementation, the first data signal line Data1, the second data signal line Data2, and the data output line SLn to which the distributor is connected extend in the first direction D1.

In an exemplary implementation, as shown in FIGS. 42 to 45, the data output line SLn, the first electrode T13-1 of the first one of the first selection transistors, and the first electrode T23-1 of the first one of the second selection transistors are formed into an integral structure. The second electrode T14-1 of the first one of the first selection transistors and the first data signal line Data1 to which the distributor is connected are formed into an integral structure, the second electrode T24-1 of the first one of the second selection transistors and the second data signal line Data2 to which the distributor is connected are formed into an integral structure, and the first electrode T13-2 and the second electrode T14-2 of the second one of the first selection transistors and the first electrode T23-2 and the second electrode T24-2 of the second one of the second selection transistors are disposed separately.

In an exemplary implementation, as shown in FIGS. 42 to 45, a shape of the first electrode T13-1 of the first one of the first selection transistors (also the first electrode T23-1 of the first one of the second selection transistors) is a strip shape and extends D1 in the first direction. The first electrode T13-1 of the first one of the first selection transistors (also the first electrode T23-1 of the first one of the second selection transistors) is connected with a first region of an active pattern of the first one of the first selection transistors (also a first region of an active pattern of the first one of the second selection transistors) through a fifth via.

In an exemplary implementation, as shown in FIGS. 42 to 45, a shape of the second electrode T14-1 of the first one of the first selection transistors is a strip shape and extends D1 in the first direction. The second electrode T14-1 of the first one of the first selection transistors is connected with a second region of the active pattern of the first one of the first selection transistors through a sixth via.

In an exemplary implementation, as shown in FIGS. 42 to 45, a shape of the second electrode T24-1 of the first one of the second selection transistors is a strip shape and extends D1 in the first direction. The second electrode T24-1 of the first one of the second selection transistors is connected with a second region of the active pattern of the first one of the second selection transistors through a seventh via.

In an exemplary implementation, as shown in FIGS. 42 to 45, a shape of the first electrode T13-2 of the second one of the first selection transistors is a strip shape and extends D1 in the first direction. The first electrode T13-2 of the second one of the first selection transistors is connected with a light shielding pattern of the second one of the first selection transistors through a third via, is connected with a first region of an active pattern of the second one of the first selection transistors through an eighth via, is connected with a gate electrode of the second one of the first selection transistors through a thirteenth via, and is connected to the second sub-selection signal line of the first selection signal line through a sixteenth via.

In an exemplary implementation, as shown in FIGS. 42 to 45, a shape of the second electrode T14-2 of the second one of the first selection transistors is a strip shape and extends in the first direction D1. The second electrode T14-2 of the second one of the first selection transistors is connected with a light shielding pattern of the first one of the first selection transistors through a first via, and is connected with a second region of the active pattern of the second one of the first selection transistors through a ninth via.

In an exemplary implementation, as shown in FIGS. 42 to 45, a shape of the first electrode T23-2 of the second one of the second selection transistors is a strip shape and extends D1 in the first direction. The first electrode T23-2 of the second one of the second selection transistors is connected with a light shielding pattern of the second one of the second selection transistors through a fourth via, is connected with a first region of an active pattern of the second one of the second selection transistors through a tenth via, is connected with a gate electrode of the second one of the second selection transistors through a fourteenth via, and is connected to a second sub-selection signal line of a second selection signal line through a seventeenth via.

In an exemplary implementation, as shown in FIGS. 42 to 45, a shape of the second electrode T24-2 of the second one of the second selection transistors is a strip shape and extends D1 in the first direction. The second electrode T24-2 of the second one of the second selection transistors is connected with a light shielding pattern of the second selection transistor through a second via, and is connected with a second region of the active pattern of the second one of the second selection transistors through an eleventh via

In an exemplary implementation, as shown in FIGS. 42 to 45, a shape of the fourth connection line LA is a strip shape and extends D1 in the first direction. The fourth connection line LA is connected with a gate electrode of the first one of the second selection transistors through the twelfth via, and is connected with a first sub-selection signal line of the second selection signal line through the fifteenth via.

In an exemplary implementation, as shown in FIGS. 44 and 45, the pattern of the second conductive layer may further include at least a first electrode T33 and a second electrode T34 of a third selection transistor, a first electrode T43 and a second electrode T44 of a fourth selection transistor, and a fifth connection line L5 and a sixth connection line L6 located in at least one distributor.

In an exemplary implementation, as shown in FIGS. 44 and 45, the second electrode T14-1 of the first one of the first selection transistors and the second electrode T34 of the third selection transistor are formed into an integral structure. The second electrode T24-1 of the first one of the second selection transistors and the second electrode T44 of the fourth selection transistor are formed into an integral structure. The first electrode T33 of the third selection transistor and the first electrode T43 of the fourth selection transistor are disposed separately.

In an exemplary implementation, as shown in FIGS. 44 and 45, a shape of the second electrode T14-1 of the first one of the first selection transistors (also the second electrode T34 of the third selection transistor) is a strip shape and extends in the first direction D1. The second electrode T14-1 of the first one of the first selection transistors (also the second electrode T34 of the third selection transistor) is also connected with a second region of an active pattern of the third selection transistor through a twenty-first via.

In an exemplary implementation, as shown in FIGS. 44 and 45, a shape of the second electrode T24-1 of the first one of the second selection transistors (also the second electrode T44 of the fourth selection transistor) is a strip shape and extends in the first direction D1. The second electrode T24-1 of the first one of the second selection transistors (also the second electrode T44 of the fourth selection transistor) is also connected with a second region of an active pattern of the fourth selection transistor through a twenty-third via.

In an exemplary implementation, as shown in FIGS. 44 to 45, a shape of the first electrode T33 of the third selection transistor is a strip shape and extends in the first direction D1. The first electrode T 33 of the third selection transistor is connected with the first region of the active pattern of the third selection transistor through a twentieth via.

In an exemplary implementation, as shown in FIGS. 44 to 45, a shape of the first electrode T43 of the fourth selection transistor is a strip shape and extends in the first direction D1. The first electrode T 43 of the fourth selection transistor is connected with the first region of the active pattern of the fourth selection transistor through a twenty-second via.

In an exemplary implementation, as shown in FIGS. 44 and 45, a shape of the fifth connecting line L5 is a polyline shape, and at least partially extends in the first direction D1. The fifth connection line L5 is connected with a light shielding pattern of the third selection transistor through an eighteenth via, is connected with the gate electrode of the third selection transistor through a twenty-fourth via, and is connected with the first sub-selection signal line of the first selection signal line through a twenty-sixth via.

In an exemplary implementation, as shown in FIGS. 44 and 45, the sixth connecting line L6 has a polyline shape, and at least partially extends in the first direction D1. The sixth connection line L6 is connected with a light shielding pattern of the fourth selection transistor through a nineteenth via, and is connected with the gate electrode of the fourth selection transistor through a twenty-fifth via.

(6) Forming a pattern of a second planarization layer includes on the base substrate on which the aforementioned patterns are formed, sequentially coating a first planarization thin film, depositing a fourth insulation thin film, and coating a second planarization thin film, patterning the first planarization thin film, the fourth insulation thin film, and the second planarization thin film by a patterning process to form a first planarization layer, a fourth insulation layer, and the pattern of the second planarization layer covering the aforementioned patterns.

Hereinafter, the manufacturing process of the display substrate provided in FIGS. 10 and 13, in which the light shielding patterns have double-layer structures, will be illustrated with one dispenser. A manufacturing process of a display substrate according to an exemplary implementation may include following steps.

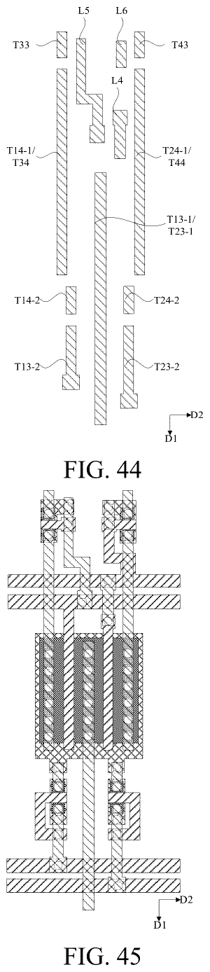

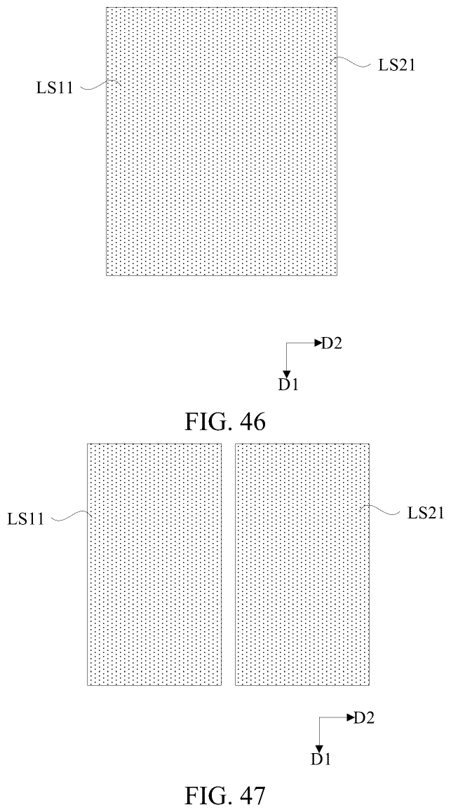

(1) Forming a pattern of a first light shielding layer on the base substrate includes: depositing a first light shielding thin film on the base substrate and patterning the first light shielding thin film by a patterning process to form the pattern of the first light shielding layer, as shown in FIGS. 46 and 47. FIG. 46 is a schematic diagram of a pattern of a first light shielding layer in FIG. 10, and FIG. 47 is a schematic diagram of a pattern of a first light shielding layer in FIG. 13.

In an exemplary implementation, as shown in FIGS. 46 and 47, the pattern of the light shielding layer may include at least a first light shielding pattern LS11 of a first selection transistor and a first light shielding pattern LS21 of a second selection transistor located in at least one distributor.

In an exemplary implementation, as shown in FIG. 46, the first light shielding pattern LS11 of the first selection transistor and the first light shielding pattern LS21 of the second selection transistor located in the same distributor are formed into an integral structure.

In an exemplary implementation, as shown in FIG. 46, a shape of the first light shielding pattern LS11 of the first selection transistor (also the first light shielding pattern LS21 of the second selection transistor) located in a same distributor may be a strip shape and may extend in the first direction D1.

In an exemplary implementation, as shown in FIG. 47, the first light shielding pattern LS11 of the first selection transistor and the first light shielding pattern LS21 of the second selection transistor located in a same distributor are disposed separately and arranged in the second direction D2.

In an exemplary implementation, as shown in FIG. 47, shapes of the first light shielding pattern LS11 of the first selection transistor and the first light shielding pattern LS21 of the second selection transistor may be a strip shape and may extend in the first direction D1.

In an exemplary implementation, as shown in FIG. 47, the first light shielding pattern LS11 of the first selection transistor and the first light shielding pattern LS21 of the second selection transistor may be symmetrical with respect to the first virtual straight line.

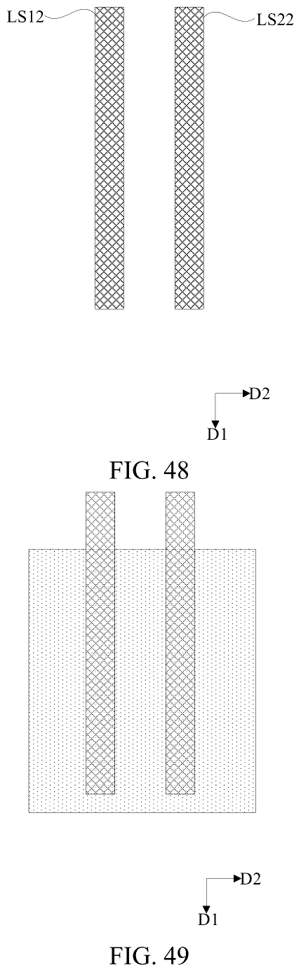

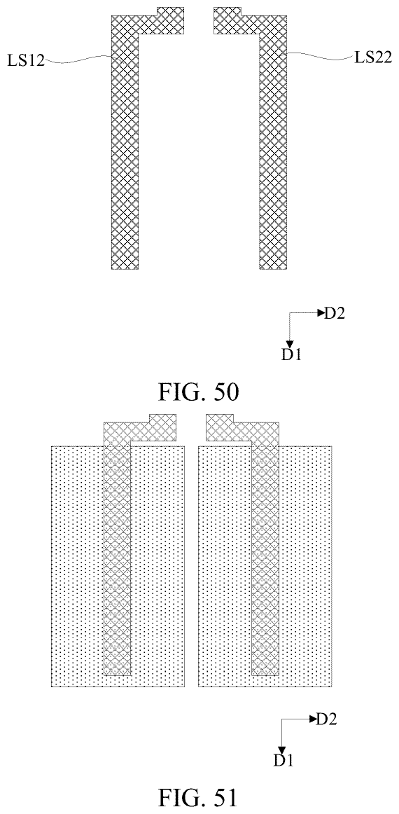

(2) Forming a pattern of a second light shielding layer on the base substrate, includes: forming a first sub-insulation thin film and a second light shielding thin film sequentially on the base substrate, patterning the second light shielding thin film by a patterning process to form a first sub-insulation layer covering the base substrate and the pattern of the second light shielding layer disposed on the first sub-insulation layer, as shown in FIGS. 48 to 51. FIG. 48 is a schematic diagram of a pattern of a second light shielding layer in FIG. 10, FIG. 49 is a schematic diagram after a pattern of a second insulation layer is formed in FIG. 10, FIG. 50 is a schematic diagram of a pattern of a second light shielding layer in FIG. 13, and FIG. 51 is a schematic diagram after a pattern of a second light shielding layer is formed in FIG. 13.

In an exemplary implementation, as shown in FIGS. 48 to 51, the pattern of the second light shielding layer may include at least a second light shielding pattern LS12 of a first selection transistor and a second light shielding pattern LS22 of a second selection transistor located in at least one distributor.

In an exemplary implementation, as shown in FIGS. 48 to 51, the second light shielding pattern LS12 of the first selection transistor and the second light shielding pattern LS22 of the second selection transistor located in a same distributor are disposed separately and arranged in the second direction D2.

In an exemplary implementation, as shown in FIGS. 48 and 49, shapes of the first light shielding pattern LS11 of the first selection transistor and the first light shielding pattern LS21 of the second selection transistor may be strip shapes and may extend in the first direction D1.

In an exemplary implementation, as shown in FIGS. 50 and 51, a shape of the first light shielding pattern LS 11 of the first selection transistor may be a shape of a “┌”, and a shape of the first light shielding pattern LS 21 of the second selection transistor may be a shape of a “┐”.

In an exemplary implementation, as shown in FIGS. 48 to 51, the first light shielding pattern LS11 of the first selection transistor and the first light shielding pattern LS21 of the second selection transistor may be symmetrical with respect to the first virtual straight line.

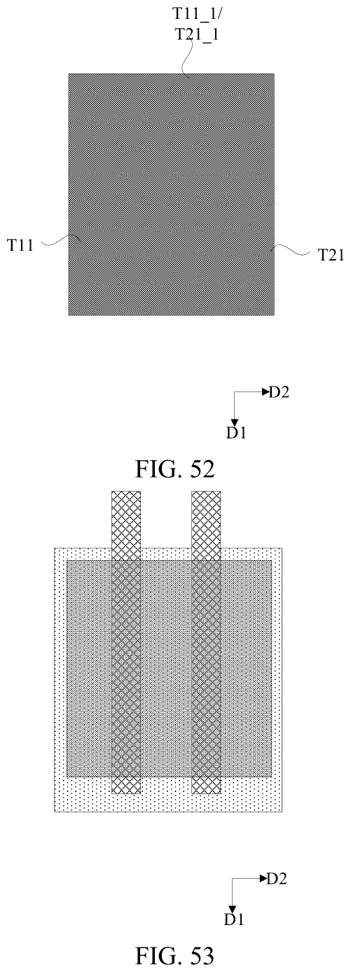

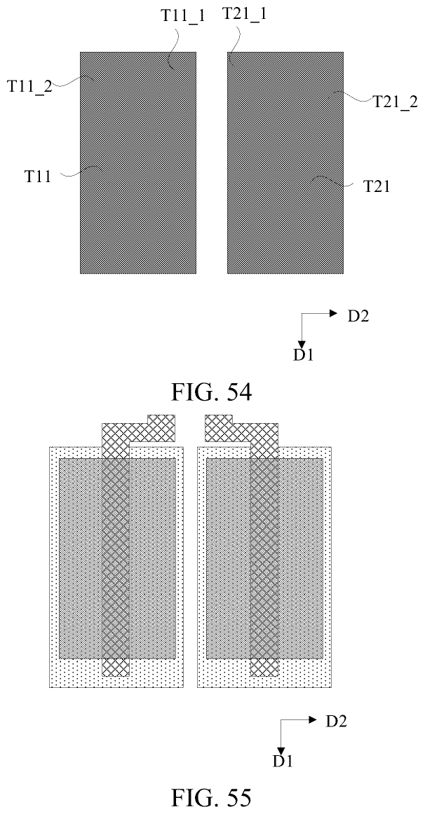

(3) Forming a pattern of a semiconductor layer. In an exemplary implementation, forming a pattern of a semiconductor layer may include sequentially depositing a second sub-insulation thin film and a semiconductor thin film on the base substrate including the aforementioned patterns, patterning the semiconductor thin film by a patterning process to form a second sub-insulation layer covering the second light shielding layer and the pattern of the semiconductor layer located on the second sub-insulation layer, as shown in FIGS. 52 to 55. FIG. 52 is a schematic diagram of a pattern of a semiconductor layer in FIG. 10, FIG. 53 is a schematic diagram after a pattern of a semiconductor layer is formed in FIG. 10, FIG. 54 is a schematic diagram of a pattern of a semiconductor layer in FIG. 13, and FIG. 55 is a schematic diagram after a pattern of a semiconductor layer is formed in FIG. 13.

In an exemplary implementation, as shown in FIGS. 52 to 55, the pattern of the semiconductor layer may include at least an active pattern T11 of a first selection transistor and an active pattern T21 of a second selection transistor located at least in a distributor.

In an exemplary implementation, as shown in FIGS. 52 and 53, the active pattern T11 of the first selection transistor and the active pattern T21 of the second selection transistor are formed into an integral structure.

In an exemplary implementation, as shown in FIGS. 52 and 53, a shape of the active pattern T11 of the first selection transistor (the active pattern T21 of the second selection transistor) may be a strip shape and extend along the first direction D1.

In an exemplary implementation, as shown in FIGS. 52 and 53, an orthographic projection of a light shielding pattern of the first selection transistor (a light shielding pattern of the first selection transistor) on the base substrate covers the active pattern T11 of the first selection transistor (the active pattern T21 of the second selection transistor).

In an exemplary implementation, an active pattern of a transistor may include a first region, a second region, and a channel region located between the first region and the second region. As shown in FIGS. 52 and 53, a first region T11_1 of the active pattern T11 of the first selection transistor and a first region T21_1 of the active pattern T21 of the second selection transistor are formed into an integral structure, and a second region T11_2 of the active pattern T11 of the first selection transistor and a second region T21_2 of the active pattern T21 of the second selection transistor are disposed separately.

In an exemplary implementation, as shown in FIGS. 54 and 55, the active pattern T11 of the first selection transistor and the active pattern T21 of the second selection transistor are disposed separately and arranged in the second direction D2.

In an exemplary implementation, as shown in FIGS. 54 and 55, shapes of the active pattern T11 of the first selection transistor and the active pattern T21 of the second selection transistor may be strip shapes and extend in the first direction D1.

In an exemplary implementation, as shown in FIGS. 54 and 55, the active pattern T11 of the first selection transistor and the active pattern T21 of the second selection transistor are symmetrical with respect to the first virtual straight line.

In an exemplary implementation, as shown in FIG. 55, the orthographic projection of the light shielding pattern of the first selection transistor on the base substrate covers the orthographic projection of the active pattern T11 of the first selection transistor on the base substrate. The orthographic projection of the light shielding pattern of the second selection transistor on the base substrate covers the orthographic projection of the active pattern T21 of the second selection transistor on the base substrate.

In an exemplary implementation, an active pattern of a transistor may include a first region, a second region, and a channel region located between the first region and the second region. As shown in FIGS. 54 and 55, the first region T11_1 of the active pattern T11 of the first selection transistor, the second region T11_2 of the active pattern T11 of the first selection transistor, the first region T21_1 of the active pattern T21 of the second selection transistor, and the second region T21_2 of the active pattern T21 of the second selection transistor are disposed separately.

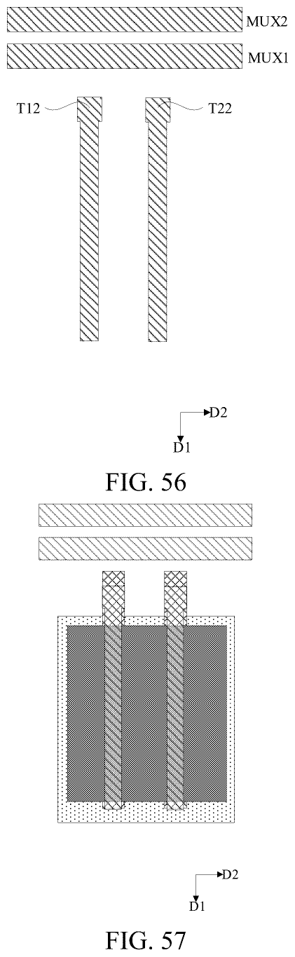

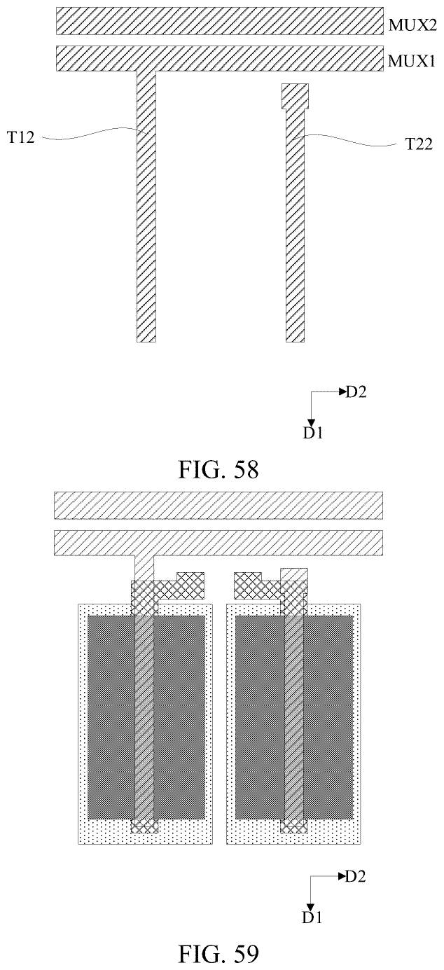

(4) Forming a pattern of a first conductive layer. In an exemplary implementation, forming a pattern of a first conductive layer may include sequentially depositing a second insulation thin film and a first conductive film on the base substrate on which the aforementioned patterns are formed, patterning the first conductive film by a patterning process to form a second insulation layer covering the pattern of the semiconductor layer and the pattern of the first conductive layer located on the second insulation layer, as shown in FIGS. 56 to 59. FIG. 56 is a schematic diagram of a pattern of a first conductive layer in FIG. 10, FIG. 57 is a schematic diagram after a pattern of a first conductive layer is formed in FIG. 10, FIG. 58 is a schematic diagram of a pattern of a first conductive layer in FIG. 13, and FIG. 59 is a schematic diagram after a pattern of a first conductive layer is formed in FIG. 13. In an exemplary implementation, the first conductive layer may be referred to as a gate metal (Gate) layer.

In an exemplary implementation, as shown in FIGS. 56 to 59, the pattern of the first conductive layer may include at least a first selection signal line MUX1, a second selection signal line MUX2, and a gate electrode T12 of a first selection transistor and a gate electrode T22 of a second selection transistor located in at least one distributor.

In an exemplary implementation, as shown in FIGS. 56 and 57, the first selection signal line MUX1 and the second selection signal line MUX2 are located on a side of the distributor close to the display area. The gate electrode T12 of the first selection transistor and the gate electrode T22 of the second selection transistor are arranged in the second direction D2.

In an exemplary implementation, as shown in FIGS. 56 and 57, the gate electrode T12 of the first selection transistor and the gate electrode T22 of the second selection transistor are disposed separately.

In an exemplary implementation, as shown in FIGS. 56 and 57, an orthographic projection of a second light shielding pattern of the first selection transistor on the base substrate covers an orthographic projection of the gate electrode of the first selection transistor on the base substrate. An orthographic projection of a second light shielding pattern of the second selection transistor on the base substrate covers an orthographic projection of the gate electrode of the second selection transistor on the base substrate.

In an exemplary implementation, as shown in FIGS. 58 and 59, the first selection signal line MUX1 and the gate electrode T12 of the first selection transistor are formed into an integral structure.

In an exemplary implementation, as shown in FIGS. 58 and 59, the orthographic projection of the second light shielding pattern of the first selection transistor on the base substrate is partially overlapped with an orthographic projection of the gate electrode of the first selection transistor on the base substrate. The orthographic projection of the second light shielding pattern of the second selection transistor on the base substrate is partially overlapped with the orthographic projection of the gate electrode of the second selection transistor on the base substrate.

In an exemplary implementation, as shown in FIGS. 56 to 59, a length of the second light shielding pattern of the first selection transistor in the second direction is larger than a length of the gate electrode of the first selection transistor in the second direction. A length of the second light shielding pattern of the second selection transistor in the second direction is larger than a length of the gate electrode of the second selection transistor in the second direction.

In an exemplary implementation, as shown in FIGS. 56 to 59, a first selection signal line MUX1 and a second selection signal line MUX2 extend in the second direction D2 and are arranged in the first direction D1.

In an exemplary implementation, as shown in FIGS. 56 to 59, shapes of the gate electrode T12 of the first selection transistor and the gate electrode T22 of the second selection transistor are strip shapes and extend in the first direction D1.

In an exemplary implementation, the first selection signal line MUX1 and the second selection signal line MUX2 may be in a design of equal width, or may be in a design of non-equal widths, may be straight lines, or may be polylines, which may not only facilitate a layout of a structure of a distributor, but also reduce the parasitic capacitance between the signal lines, which is not limited here in the present disclosure.

In an exemplary implementation, the gate electrode T12 of the first selection transistor is disposed across the active pattern of the first selection transistor, and the gate electrode T22 of the second selection transistor is disposed across the active pattern of the second selection transistor, that is, an extension direction of a gate electrode of at least one transistor and an extension direction of an active pattern thereof are perpendicular to each other.

In an exemplary implementation, after the pattern of the first conductive layer is formed, a conductive treatment may be performed on the semiconductor layer by using the first conductive layer as a shield. Regions of the semiconductor layer, which are shielded by the first conductive layer, form channel regions of the first selection transistor and the second selection transistor, and regions of the semiconductor layer, which are not shielded by the first conductive layer, are made to be conductive, that is, a first region and a second region of an active pattern of any one of the first selection transistor and the second selection transistor are all made to be conductive.

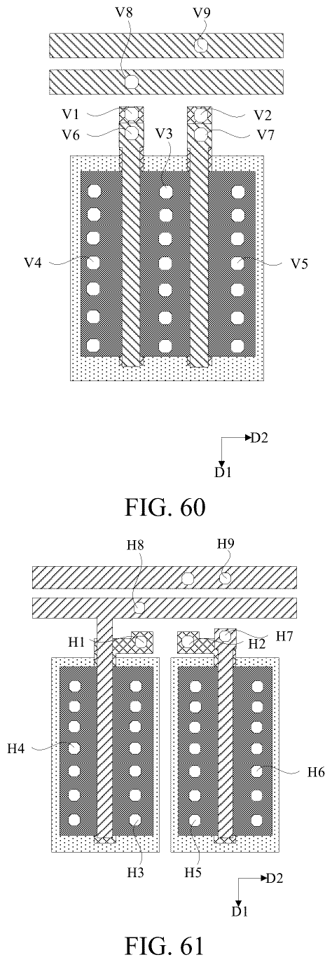

(5) Forming a pattern of a third insulation layer. In an exemplary implementation, forming a pattern of a third insulation layer may include: depositing a third insulation thin film on the base substrate on which the aforementioned patterns are formed, patterning the third insulation thin film by a patterning process to form a third insulation layer covering the first conductive layer, and providing a plurality of vias on the third insulation layer, as shown in FIGS. 60 and 61. FIG. 60 is a schematic diagram of a pattern of a third insulation layer in FIG. 10, and FIG. 61 is a schematic diagram of a pattern of a third insulation layer in FIG. 13.

In an exemplary implementation, as shown in FIG. 60, the plurality of vias of the third insulation layer may include at least a first via V1 to a ninth via V9 located in at least one distributor.

In an exemplary implementation, as shown in FIG. 60, an orthographic projection of the first via V1 on the base substrate is within a range of an orthographic projection of a second light shielding pattern of a first selection transistor on the base substrate, the first insulation layer and the second insulation layer within the first via V1 are etched away to expose a surface of the second light shielding pattern of the first selection transistor, and the first via V1 is configured to connect a first connection line to be formed subsequently with the second light shielding pattern of the first selection transistor through this via.

In an exemplary implementation, as shown in FIG. 60, an orthographic projection of a second via V2 on the base substrate is within a range of an orthographic projection of a second light shielding pattern of a second selection transistor on the base substrate, the first insulation layer and the second insulation layer within the second via V2 are etched away to expose a surface of the second light shielding pattern of the second selection transistor, and the second via V2 is configured to connect a second connection line to be formed subsequently with the second light shielding pattern of the second selection transistor through this via.

In an exemplary implementation, as shown in FIG. 60, orthographic projections of third vias V3 on the base substrate are within a range of an orthographic projection of a first region of an active pattern of the first selection transistor (also a first region of an active pattern of the second selection transistor) on the base substrate, the second insulation layer within the third vias V3 is etched away to expose a surface of the first region of the active pattern of the first selection transistor (also the first region of the active pattern of the second selection transistor), and the third vias V3 are configured to connect a first electrode of the first selection transistor (also a first electrode of the second selection transistor) to be formed subsequently with the first region of the active pattern of the first selection transistor (also the first region of the active pattern of the second selection transistor) through these vias.

In an exemplary implementation, as shown in FIG. 60, orthographic projections of fourth vias V4 on the base substrate is within a range of an orthographic projection of a second region of the active pattern of the first selection transistor on the base substrate, the second insulation layer within the fourth vias V4 is etched away to expose a surface of the second region of the active pattern of the first selection transistor, and the fourth vias V4 are configured to connect a second electrode of the first selection transistor to be formed subsequently with the second region of the active pattern of the first selection transistor through these vias.

In an exemplary implementation, as shown in FIG. 60, orthographic projections of fifth vias V5 on the base substrate are located within a range of an orthographic projection of a second region of the active pattern of the second selection transistor on the base substrate, the second insulation layer within the fifth vias V5 is etched away to expose a surface of the second region of the active pattern of the second selection transistor, and the fifth vias V5 are configured to connect a second electrode of the second selection transistor to be formed subsequently with the second region of the active pattern of the second selection transistor through these vias.

In an exemplary implementation, as shown in FIG. 60, an orthographic projection of a sixth via V6 on the base substrate is within a range of an orthographic projection of a gate electrode of the first selection transistor on the base substrate, the sixth via V6 exposes a surface of the gate electrode of the first selection transistor, and the sixth via V6 is configured to connect the first connection line to be formed subsequently with the gate electrode of the first selection transistor through this via.

In an exemplary implementation, as shown in FIG. 60, an orthographic projection of a seventh via V7 on the base substrate is within a range of an orthographic projection of a gate electrode of the second selection transistor on the base substrate, the seventh via V7 exposes a surface of the gate electrode of the second selection transistor, and the seventh via V7 is configured to connect the second connection line to be formed subsequently with the gate electrode of the second selection transistor through this via.

In an exemplary implementation, as shown in FIG. 60, an orthographic projection of an eighth via V8 on the base substrate is within a range of an orthographic projection of a first selection signal line on the base substrate, the eighth via V8 exposes a surface of the first selection signal line, and the eighth via V8 is configured to connect the first connection line to be formed subsequently with the first selection signal line through this via.

In an exemplary implementation, as shown in FIG. 60, an orthographic projection of the ninth via V9 on the base substrate is located within a range of an orthographic projection of a second selection signal line on the base substrate, the ninth via V9 exposes a surface of the second selection signal line, and the ninth via V9 is configured to connect the second connection line and the third connection line to be formed subsequently with the second selection signal line through this via.

In an exemplary implementation, as shown in FIG. 60, a quantity of any one of the third vias V3, the fourth vias V4, and the fifth vias V5 is at least one, for example, may be one, or may be multiple, and any one of the third vias V3, the fourth vias V4, and the fifth vias V5 may be arranged in the first direction D1. FIG. 60 is illustrated by taking an example in which the quantity of any one of the third vias V3, the fourth vias V4, and the fifth vias V5 is multiple.

In an exemplary implementation, as shown in FIG. 61, a plurality of vias of the third insulation layer may include at least a first via H1 to ninth vias H9 located in at least one distributor.

In an exemplary implementation, as shown in FIG. 61, an orthographic projection of the first via H1 on the base substrate is within a range of an orthographic projection of a second light shielding pattern of a first one of the first selection transistors on the base substrate, the first insulation layer and the second insulation layer within the first via H1 are etched away to expose a surface of the second light shielding pattern of the first one of the first selection transistors, and the first via H1 is configured to connect a first connection line to be formed subsequently with the second light shielding pattern of the first selection transistor through this via.

In an exemplary implementation, as shown in FIG. 61, an orthographic projection of a second via H2 on the base substrate is within a range of an orthographic projection of a second light shielding pattern of a second selection transistor on the base substrate, the first insulation layer and the second insulation layer within the second via H2 are etched away to expose a surface of the second light shielding pattern of the second selection transistor, and the second via H2 is configured to connect a second connection line to be formed subsequently with the second light shielding pattern of the second selection transistor through this via.

In an exemplary implementation, as shown in FIG. 61, orthographic projections of third vias H3 on the base substrate are located within a range of an orthographic projection of a first region of an active pattern of a first selection transistor on the base substrate, the second insulation layer within the third vias H3 is etched away to expose a surface of the first region of the active pattern of the first selection transistor, and the third vias H3 are configured to connect a first electrode of the first selection transistor (also a first electrode of a second selection transistor) to be formed subsequently with the first region of the active pattern of the first selection transistor through these vias.

In an exemplary implementation, as shown in FIG. 61, orthographic projections of fourth vias H4 on the base substrate are within a range of an orthographic projection of a second region of the active pattern of the first selection transistor on the base substrate, the second insulation layer within the fourth vias H4 is etched away to expose a surface of the second region of the active pattern of the first selection transistor, and the fourth vias H4 are configured to connect a second electrode of the first selection transistor to be formed subsequently with the second region of the active pattern of the first selection transistor through these vias.

In an exemplary implementation, as shown in FIG. 61, orthographic projections of fifth vias H5 on the base substrate are located within a range of an orthographic projection of a first region of an active pattern of the second selection transistor on the base substrate, the second insulation layer within the fifth vias H5 is etched away to expose a surface of the first region of the active pattern of the second selection transistor, and the fifth vias H5 are configured to connect the first electrode of the first selection transistor (also the first electrode of the second selection transistor) to be formed subsequently with the first region of the active pattern of the second selection transistor through these vias.

In an exemplary implementation, as shown in FIG. 61, orthographic projections of sixth vias H6 on the base substrate are located within a range of an orthographic projection of a second region of the active pattern of the second selection transistor on the base substrate, the second insulation layer within the sixth vias H6 is etched away to expose a surface of the second region of the active pattern of the second selection transistor, and the sixth vias H6 are configured to connect a second electrode of the second selection transistor to be formed subsequently with the second region of the active pattern of the second selection transistor through these vias.

In an exemplary implementation, as shown in FIG. 61, an orthographic projection of a seventh via H7 on the base substrate is within a range of an orthographic projection of a gate electrode of the second selection transistor on the base substrate, the seventh via H7 exposes a surface of the gate electrode of the second selection transistor, and the seventh via H7 is configured to connect a third connection line to be formed subsequently with the gate electrode of the second selection transistor through this via.

In an exemplary implementation, as shown in FIG. 61, an orthographic projection of an eighth via H8 on the base substrate is within a range of an orthographic projection of a first selection signal line on the base substrate, the eighth via H8 exposes a surface of the first selection signal line, and the eighth via H8 is configured to connect the first connection line to be formed subsequently with the first selection signal line through this via.

In an exemplary implementation, as shown in FIG. 61, an orthographic projection of the ninth via H9 on the base substrate is located within a range of an orthographic projection of a second selection signal line on the base substrate, the ninth via H9 exposes a surface of the second selection signal line, and the ninth via H9 is configured to connect the second connection line and a third connection line to be formed subsequently with the second selection signal line through this via.

In an exemplary implementation, as shown in FIG. 61, a quantity of any one of the third vias H3, the fourth vias H4, the fifth vias H5, and the sixth vias H6 is at least one, for example, may be one, or may be multiple, and any one of the third vias H3, the fourth vias H4, the fifth vias H5, and the sixth vias H6 may be arranged in the first direction D1. FIG. 61 is illustrated by taking an example in which the quantity of the third vias H3, the fourth vias H4, the fifth vias H5, and the sixth vias H6 is multiple.

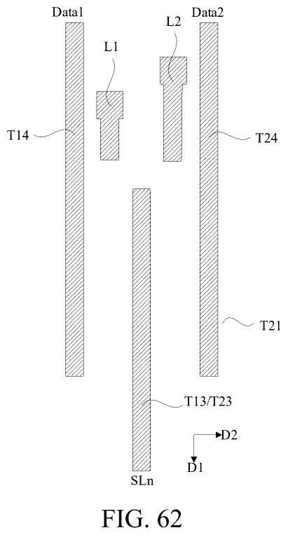

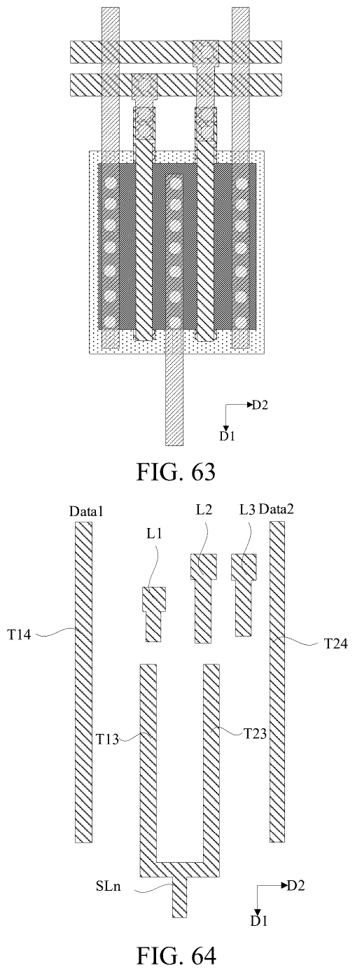

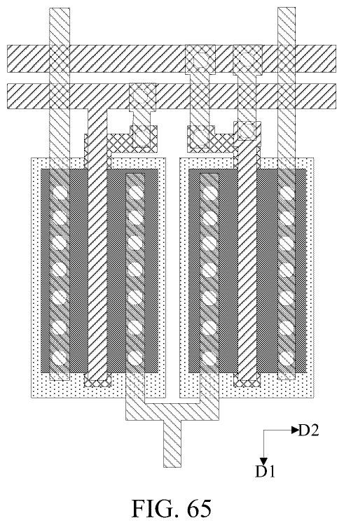

(6) Forming a pattern of a second conductive layer. In an exemplary implementation, forming a pattern of a second conductive layer may include: depositing a second conductive thin film on the base substrate on which the aforementioned patterns are formed, patterning the second conductive thin film by a patterning process to form the pattern of the second conductive layer disposed on the third insulation layer, as shown in FIGS. 62 to 65. FIG. 62 is a schematic diagram of a pattern of a second conductive layer in FIG. 10, FIG. 63 is a schematic diagram after a pattern of a second conductive layer is formed in FIG. 10, FIG. 64 is a schematic diagram of a pattern of a second conductive layer in FIG. 13, and FIG. 65 is a schematic diagram after a pattern of a second conductive layer is formed in FIG. 13. In an exemplary implementation, the second conductive layer may be referred to as a Source Drain metal (SD) layer.

In an exemplary implementation, as shown in FIGS. 62 to 65, the pattern of the second conductive layer may include at least a first data signal line Data1, a second data signal line Data2, and a data output line SLn to which the distributor is connected, and a first electrode T13 and a second electrode T14 of a first selection transistor, a first electrode T23 and a second electrode T24 of a second selection transistor, and a first connection line L1 and a second connection line L2 located in at least one distributor.

In an exemplary implementation, as shown in FIGS. 64 and 65, the pattern of the second conductive layer may include at least a third connection line L3.

In an exemplary implementation, the first data signal line Data1, the second data signal line Data2, and the data output line SLn to which the distributor is connected extend in the first direction D1.

In an exemplary implementation, the data output line SLn, the first electrode T13 of the first selection transistor, and the first electrode T23 of the second selection transistor are formed into an integral structure, the second electrode T14 of the first selection transistor and the first data signal line Data1 to which the distributor is connected are formed into an integral structure, and the second electrode T24 of the second selection transistor and the second data signal line Data2 to which the distributor is connected are formed into an integral structure.

In an exemplary implementation, as shown in FIGS. 62 and 63, shapes of the first electrode T13 of the first selection transistor and the first electrode T23 of the second selection second selection transistor are line shapes.

In an exemplary implementation, as shown in FIGS. 64 and 65, the shapes of the first electrode T13 of the first selection transistor and the first electrode T23 of the second selection second selection transistor is groove shapes in which openings face the display area.

In an exemplary implementation, as shown in FIGS. 62 to 65, the first electrode T13 of the first selection transistor (also the first electrode T23 of the second selection transistor) extends at least partially in the first direction D1. As shown in FIG. 63, the first electrode T13 of the first selection transistor (also the first electrode T23 of the second selection transistor) is connected with a first region of an active pattern of the first selection transistor (also a first region of an active pattern of the second selection transistor) through third vias, and as shown in FIG. 65, the first electrode T13 of the first selection transistor (also the first electrode T23 of the second selection transistor) is connected with the first region of the active pattern of the first selection transistor through third vias, and is connected with the first region of the active pattern of the second selection transistor through fifth vias.

In an exemplary implementation, as shown in FIGS. 62 and 63, a shape of the first electrode T13 of the first selection transistor (which is also the first electrode T23 of the second selection transistor) may be a line shape.

In an exemplary implementation, as shown in FIGS. 64 and 65, a shape of the first electrode T13 of the first selection transistor (which is also the first electrode T23 of the second selection transistor) may be a polyline shape.

In an exemplary implementation, as shown in FIGS. 62 to 65, a shape of the second electrode T14 of the first selection transistor is a strip shape and extends in the first direction D1. As shown in FIGS. 63 and 65, the second electrode T14 of the first selection transistor is connected with a second region of an active pattern of the first selection transistor through fourth vias.

In an exemplary implementation, as shown in FIGS. 62 to 65, a shape of the second electrode T24 of the second selection transistor is a strip shape and extends in the first direction D1. As shown in FIG. 63, the second electrode T24 of the second selection transistor is connected with a second region of an active pattern of the second selection transistor through fifth vias. As shown in FIG. 65, the second electrode T24 of the second selection transistor is connected with a second region of an active pattern of the second selection transistor through sixth vias.

In an exemplary implementation, as shown in FIGS. 62 to 65, a shape of the first connection line L1 is a strip shape and extends in the first direction D1. As illustrated in FIG. 63, the first connection line L1 is connected with a light shielding pattern of the first selection transistor through a first via, is connected with a gate electrode of the first selection transistor through a sixth via, and is connected with a first selection signal line through an eighth via. As shown in FIG. 65, the first connection line L1 is connected with a light shielding pattern of the first selection transistor through a first via, and is connected with a first selection signal line through an eighth via In an exemplary implementation, as shown in FIGS. 62 to 65, a shape of the second connection line L2 is a strip shape and extends in the first direction D1. As shown in FIG. 63, the second connection line L2 is connected with a light shielding pattern of the second selection transistor through a second via, is connected with a gate electrode of the second selection transistor through a seventh via, and is connected to a second selection signal line through a ninth via. As shown in FIG. 65, the second connection line L2 is connected with a light shielding pattern of the second selection transistor through a second via, and is connected to a second selection signal line through a ninth via.

In an exemplary implementation, as shown in FIGS. 64 and 65, a shape of the third connection line L3 is a strip shape and extends in the first direction D1. The third connection line L3 is connected with the gate electrode of the second selection transistor through a seventh via, and is connected with the second selection signal line through a ninth via.

(7) Forming a pattern of a second planarization layer includes on the base substrate on which the aforementioned patterns are formed, sequentially coating a first planarization thin film, depositing a fourth insulation thin film, and coating a second planarization thin film, patterning the first planarization thin film, the fourth insulation thin film, and the second planarization thin film by a patterning process to form a first planarization layer, a fourth insulation layer, and the pattern of the second planarization layer covering the aforementioned patterns.

In an exemplary implementation, the semiconductor layer may be a metal oxide layer. Herein, the metal oxide layer may be an oxide including indium and tin, an oxide including tungsten and indium, an oxide including tungsten, indium, and zinc, an oxide including titanium and indium, an oxide including titanium, indium, and tin, an oxide including indium and zinc, an oxide including silicon, indium, and tin, or an oxide including indium or gallium and zinc. The metal oxide layer may be a single layer, a double-layer, or a multi-layer.

In an exemplary implementation, the light shielding layer, the first light shielding layer, the second light shielding layer, the first conductive layer, and the second conductive layer may be made of a metal material such as any one or more of silver (Ag), copper (Cu), aluminum (Al), and molybdenum (Mo), or an alloy material of the above metals, such as an aluminum neodymium alloy (AlNd) or a molybdenum niobium alloy (MoNb), which may be a single-layer structure, or a multilayer composite structure such as Mo/Cu/Mo, etc.

In an exemplary implementation, the first sub-insulation layer, the second sub-insulation layer, the first insulation layer, the second insulation layer, the third insulation layer, and the fourth insulation layer may be made of any one or more of silicon oxide (SiOx), silicon nitride (SiNx), and silicon oxynitride (SiON), and may be a single layer, a multilayer layer, or a composite layer.

In an exemplary implementation, the first planarization layer and the second planarization layer may be made of an organic material, such as resin or the like.

An embodiment of the present disclosure further provides a display apparatus including a display substrate.

The display substrate is the display substrate according to any of the aforementioned embodiments, and has similar implementation principles and implementation effects, which will not be repeated here.

In an exemplary implementation, the display apparatus may be any product or component with a display function, such as a liquid crystal panel, electronic paper, an OLED panel, an Active-Matrix Organic Light Emitting Diode (AMOLED) panel, a mobile phone, a tablet computer, a television, a display, a notebook computer, a digital photo frame, or a navigator.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although implementations of the present disclosure are disclosed above, contents described are only implementations used for ease of understanding of the present disclosure, but not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A display substrate provided with a display area and a non-display area, comprising a base substrate, a plurality of data signal lines disposed on the base substrate and at least partially located in the display area, at least two selection signal lines, a plurality of data output lines, and a demultiplexer located in the non-display area, wherein the demultiplexer comprises a plurality of selection transistors, and a selection transistor is respectively electrically connected with a selection signal line, a data signal line, and a data output line;
the selection transistor comprises a light shielding pattern, an active pattern, and a gate electrode, wherein for a same selection transistor, one of a light shielding pattern and a gate electrode is located on a side of an active pattern close to the base substrate, the other of the light shielding pattern and the gate electrode is located on a side of the active pattern away from the base substrate, and an orthographic projection of the light shielding pattern on the base substrate is at least partially overlapped with an orthographic projection of the gate electrode on the base substrate; and
the light shielding pattern and the gate electrode of the selection transistor are respectively electrically connected with a selection signal line to which the selection transistor is connected.

2. The display substrate according to claim 1, wherein for the same selection transistor, the orthographic projection of the light shielding pattern on the base substrate covers an orthographic projection of the active pattern on the base substrate, and the orthographic projection of the gate electrode on the base substrate is at least partially overlapped with the orthographic projection of the active pattern on the base substrate.

13. The display substrate according to claim 1, wherein the selection signal lines comprise a first selection signal line to an M-th selection signal line, and the data output lines comprise a first data output line to an N-th data output line;
the demultiplexer comprises N distributors, wherein an n-th distributor is respectively electrically connected with the first selection signal line to the M-th selection signal line, an n-th data output line, and the M data signal lines, and at least one of the distributors comprises a first selection transistor to an M-th selection transistor;
in the n-th distributor, a light shielding pattern of an m-th selection transistor and a gate electrode of the m-th selection transistor are respectively electrically connected with an m-th selection signal line, wherein 1≤m≤M, and 1≤n≤N;
the data signal lines and the data output lines extend at least partially in a first direction, and the selection signal lines extend at least partially in a second direction, wherein the first direction intersects with the second direction.

4. The display substrate according to claim 3, wherein the light shielding pattern has a single-layer structure or a double-layer structure;
when the light shielding pattern has the double-layer structure, the light shielding pattern comprises a first light shielding pattern and a second light shielding pattern, the first light shielding pattern is located on a side of the second light shielding pattern close to the base substrate, and an orthographic projection of the first light shielding pattern on the base substrate is at least partially overlapped with an orthographic projection of the second light shielding pattern on the base substrate; and
the first light shielding pattern of the light shielding pattern of the selection transistor is insulated from the selection signal line to which the selection transistor is connected, and the second light shielding pattern of the light shielding pattern of the selection transistor is electrically connected with the selection signal line to which the selection transistor is connected.

5. The display substrate according to claim 4, wherein when the light shielding pattern has the double-layer structure, a length of the second light shielding pattern in the second direction is larger than a length of the gate electrode of the selection transistor in the second direction.

6. The display substrate according to claim 4, wherein when M=2, the n-th distributor comprises: at least one first selection transistor and at least one second selection transistor;
a first electrode of the at least one first selection transistor and a first electrode of the at least one second selection transistor are respectively electrically connected with the n-th data output line, a second electrode of the at least one first selection transistor is electrically connected with a first data signal line to which the n-th distributor is connected, and a second electrode of the at least one second selection transistor is electrically connected with a second data signal line to which the n-th distributor is connected.

7. The display substrate according to claim 6, wherein when light shielding patterns have single-layer structures, a light shielding pattern of the a first selection transistor and a light shielding pattern of the a second selection transistor located in a same distributor are disposed at an interval and arranged in the second direction, and an active pattern of the first selection transistor and an active pattern of the second selection transistor located in the same distributor are arranged at an interval and arranged in the second direction.

8. The display substrate according to claim 6, wherein when light shielding patterns have double-layer structures, a first light shielding pattern of a first selection transistor and a first light shielding pattern of a second selection transistor are a same light shielding pattern, a second light shielding pattern of the first selection transistor and a second light shielding pattern of the second selection transistor are disposed at an interval and arranged in the second direction, and an active pattern of the first selection transistor and an active pattern of the second selection transistor are a same active pattern.

9. The display substrate according to claim 6, wherein when light shielding patterns have double-layer structures, a first light shielding pattern of a first selection transistor and a first light shielding pattern of a second selection transistor are disposed at an interval and arranged in the second direction, a second light shielding pattern of the first selection transistor and a second light shielding pattern of the second selection transistor are disposed at an interval and arranged in the second direction, and an active pattern of the first selection transistor and an active pattern of the second selection transistor are disposed at an interval and arranged in the second direction.

10. The display substrate according to claim 7, wherein a structure of the first selection transistor and a structure of the second selection transistor located in the same distributor are at least partially symmetrical with respect to a first virtual straight line, and an extension direction of the first virtual straight line is parallel to the first direction.

11. The display substrate according to claim 4, wherein when M=2 and light shielding patterns have single layer structures, the n-th distributor comprises: two first selection transistors and two second selection transistors;
for the n-th distributor, a first electrode of a first one of the first selection transistors is electrically connected with the n-th data output line, a second electrode of the first one of the first selection transistors is electrically connected with a first data signal line to which the n-th distributor is connected, a first electrode of a second one of the first selection transistors is electrically connected with the first selection signal line, a second electrode of the second one of the first selection transistors is electrically connected with a light shielding pattern of the first one of the first selection transistors; a first electrode of a first one of the second selection transistors is electrically connected with the n-th data output line, a second electrode of the first one of the second selection transistors is electrically connected with a second data signal line to which the n-th distributor is connected, a first electrode of a second one of the second selection transistors is electrically connected with a second selection signal line, a second electrode of the second one of the second selection transistors is electrically connected with a light shielding pattern of the first one of the second selection transistors.

12. The display substrate according to claim 11, wherein the light shielding pattern of the first one of the first selection transistors and the light shielding pattern of the first one of the second selection transistors are a same light shielding pattern, and an active pattern of the first one of the first selection transistors and an active pattern of the first one of the second selection transistors are a same light shielding pattern; a light shielding pattern of the second one of the first selection transistors and a light shielding pattern of the second one of the second selection transistors are disposed at an interval and arranged in the second direction, and an active pattern of the second one of the first selection transistors and an active pattern of the second one of the second selection transistors are disposed at an interval and arranged in the second direction.

13. The display substrate according to claim 11, wherein any one of the selection signal lines comprises: a first selection sub-signal line and a second selection sub-signal line, wherein the first selection sub-signal line of any one of the selection signal lines is located on a side of the demultiplexer close to the display area, and the second selection sub-signal line of any one of the selection signal lines is located on a side of the demultiplexer away from the display area; and
a gate electrode of the first one of the first selection transistors is electrically connected with a first selection sub-signal line of the first selection signal line, a gate electrode of the first one of the second selection transistors is electrically connected with a first selection sub-signal line of the second selection signal line, a gate electrode and the first electrode of the second one of the first selection transistors are respectively electrically connected with a second selection sub-signal line of the first selection signal line, and a gate electrode and the first electrode of the second one of the second selection transistors are respectively electrically connected with a second selection sub-signal line of the second selection signal line.

14. The display substrate according to claim 13, wherein the first one of the first selection transistors and the second one of the first selection transistors are arranged in the first direction, and the first one of the second selection transistors and the second one of the second selection transistors are arranged in the first direction; and
a structure of the first one of the first selection transistors and a structure of the first one of the second selection transistors are at least partially symmetrical with respect to a second virtual straight line, a structure of the second one of the first selection transistors and a structure of the second one of the second selection transistors are at least partially symmetrical with respect to the second virtual straight line, and an extension direction of the second virtual straight line is parallel to the first direction.

15. The display substrate according to claim 13, wherein the n-th distributor further comprises: a third selection transistor and a fourth selection transistor; the first one of the first selection transistors is electrically connected with the first data signal line to which the n-th distributor is connected through the third selection transistor, and the first one of the second selection transistors is electrically connected with the second data signal line to which the n-th distributor is connected through the fourth selection transistor;
a gate electrode and a light shielding pattern of the third selection transistor are respectively electrically connected with the first sub-selection signal line of the first selection signal line, a first electrode of the third selection transistor is electrically connected with the first data signal line to which the n-th distributor is connected, and a second electrode of the third selection transistor is electrically connected with the second electrode of the first one of the first selection transistors; and
a gate electrode and a light shielding pattern of the fourth selection transistor are respectively electrically connected with the first sub-selection signal line of the second selection signal line, a first electrode of the fourth selection transistor is electrically connected with the second data signal line to which the n-th distributor is connected, and a second electrode of the fourth selection transistor is electrically connected with the second electrode of the first one of the second selection transistors.

16. The display substrate according to claim 15, wherein the light shielding pattern of the third selection transistor and the light shielding pattern of the fourth selection transistor are disposed at an interval and arranged in the second direction, and an active pattern of the third selection transistor and an active pattern of the fourth selection transistor are disposed at an interval and arranged in the second direction.

17. The display substrate according to claim 16, wherein the third selection transistor and the fourth selection transistor are located on a side of the first sub-selection signal line close to the display area, and a structure of the third selection transistor and a structure of the fourth selection transistor are at least partially symmetrical with respect to the second virtual straight line.

18. The display substrate according to claim 4, wherein when light shielding patterns have single-layer structures, the display substrate comprises a light shielding layer, a semiconductor layer, a first conductive layer, and a second conductive layer sequentially stacked on the base substrate;
the light shielding layer comprises at least: light shielding patterns of the selection transistors;
the semiconductor layer comprises at least: active patterns of the selection transistors;
the first conductive layer comprises at least: gate electrodes of the selection transistors and the selection signal lines; and
the second conductive layer comprises at least: the data signal lines, the data output lines, first electrodes and second electrodes of the selection transistors.

19. The display substrate according to claim 4, wherein when light shielding patterns have double-layer structures, the display substrate comprises a first light shielding layer, a second light shielding layer, a semiconductor layer, a first conductive layer, and a second conductive layer sequentially stacked on the base substrate;
the first light shielding layer comprises at least: first light shielding patterns of the selection transistors;
the second light shielding layer comprises at least: second light shielding patterns of the selection transistors;
the semiconductor layer comprises at least: active patterns of the selection transistors;
the first conductive layer comprises at least: gate electrodes of the selection transistors and the selection signal lines; and
the second conductive layer comprises at least: the data signal lines, the data output lines, first electrodes and second electrodes of the selection transistors.

20. A display apparatus, comprising: the display substrate according to claim 1.
